(19) United States
(12) Patent Application Publication
(10) Pub. No.: US 2011/0085382 A1
(43) Pub. Date: Apr. 14, 2011

(54) Universal dual charge-retaining transistor flash NOR cell, a dual charge-retaining transistor flash NOR cell array, and method for operating same

(75) Inventors: Peter Wung Lee, Saratoga, CA (US); Fu-Chang Hsu, (US)

(73) Assignee: Aplus Flash Technology, Inc.

(21) Appl. No.: 12/925,010

(22) Filed: Oct. 12, 2010

Related U.S. Application Data
(60) Provisional application No. 61/278,900, filed on Oct. 13, 2009.

(51) Int. Cl. G11C 16/04; H01L 29/792

(52) U.S. Cl. 365/185.18; 257/324; 257/E29.309

(57) ABSTRACT

A NOR flash memory cell is formed of dual serially connected charge retaining transistors. A drain/source of a first of the dual charge retaining transistors connected to a local bit line and a source/drain of a second of the dual charge retaining transistors connected to a local source line. The drain/sources of the commonly connected dual serially connected charge retaining transistors are connected solely together. The drain/sources and source drains are formed in a diffusion well. In some embodiments, the diffusion well is formed in a deep diffusion well. The dual serially connected charge retaining transistors are N-channel or P-channel charge retaining transistors with the charge retaining layers being either floating gate or SONOS charge trapping layers. Selected charge retaining transistors are programmed by a combination of a band-to-band tunneling and a Fowler-Nordheim tunneling and erased by a Fowler Nordheim tunneling.

This application claims priority under 35 U.S.C. §119 to U.S. Provisional Patent Application Ser. No. 61/278,900, filed on Oct. 13, 2009, assigned to the same assignee as the present invention, and incorporated herein by reference in its entirety.

### RELATED PATENT APPLICATIONS

U.S. patent application Ser. No. 12/387,771, filed on May 7, 2009 assigned to the same assignee as the present invention, and incorporated herein by reference in its entirety.

U.S. patent application Ser. No. 12/455,337, filed on Jun. 1, 2009 assigned to the same assignee as the present invention, and incorporated herein by reference in its entirety.

U.S. patent application Ser. No. 12/658,121, filed on Feb. 3, 2010 assigned to the same assignee as the present invention, and incorporated herein by reference in its entirety.

U.S. patent application Ser. No. 12/806,848, filed on Jul. 15, 2010 assigned to the same assignee as the present invention, and incorporated herein by reference in its entirety.

### BACKGROUND OF THE INVENTION

1. Field of the Invention

This invention relates generally to nonvolatile memory array structure and operation. More particularly, this invention relates to a NAND-like NOR flash nonvolatile memory device structure and operation.

2. Description of Related Art

Nonvolatile memory is well known in the art. The different types of nonvolatile memory include Read-Only-Memory (ROM), Electrically Programmable Read Only Memory (EPROM), Electrically Erasable Programmable Read Only Memory (EEPROM), NOR Flash Memory, and NAND Flash Memory. In current applications such as personal digital assistants, cellular telephones, notebook and laptop computers, voice recorders, global positioning systems, etc., the Flash Memory has become one of the more popular types of Nonvolatile Memory. Flash Memory has the combined advantages of the high density, small silicon area, low cost and can be repeatedly programmed and erased with a single low-voltage power supply voltage source.

The Flash Memory structures known in the art employ a charge retaining mechanism such as charge storage or a charge trapping. In a charge storage mechanism, as with a floating gate nonvolatile memory, the charge representing digital data is stored on a floating gate of the device. The stored charge modifies the threshold voltage of the floating gate memory cell to determine the digital data stored in the floating gate nonvolatile memory cell. In a charge trapping mechanism, as in a Silicon-Oxide-Nitride-Oxide-Silicon (SONOS) or Metal-Oxide-Nitride-Oxide-Silicon (MONOS) type cell, the charge is trapped in a charge trapping layer between two insulating layers. The charge trapping layer in the SONOS/MONOS devices has a relatively high dielectric constant (k) such Silicon Nitride (SiNx).

A present day flash nonvolatile memory is divided into two major product categories such as the fast random-access, asynchronous NOR flash nonvolatile memory and the slower serial-access, synchronous NAND flash nonvolatile memory. NOR flash nonvolatile memory as presently designed is the high pin-count memory with multiple external address and data pins along with appropriate control signal pins. One disadvantage of NOR flash nonvolatile memory is as the density is doubled, the number of its required external pin count increases by one due to the adding of one more external address pin to double the address space. In contrast, NAND flash nonvolatile memory has an advantage of having a smaller pin-count than NOR with no address input pins. As density increases, the NAND flash nonvolatile memory pin count is always kept constant. Both main-streamed NAND and NOR flash nonvolatile memory cell structures in production at the present time use one charge retaining (charge storage or charge trapping) transistor memory cell that stores one bit of data as charge or as it commonly referred to as a single-level program cell (SLC). They are respectively referred as one-bit/one transistor NAND cell or NOR cell, storing a single-level programmed data in the cell.

The NAND and NOR flash nonvolatile memories provide the advantage of in-system program and erase capabilities and have a specification for providing at least is 100K endurance cycles. In addition, both single-chip NAND and NOR flash nonvolatile memory products can provide giga-byte density because their highly-scalable cell sizes. For instance, presently a one-bit/one transistor NAND cell size is kept at ˜4λ² (λ being a minimum feature size in a semiconductor process), while NOR cell size is ˜10λ². Furthermore, in addition to storing data as a single-level program cell having two voltage thresholds (Vt0 and Vt1), both one transistor NAND and NOR flash nonvolatile memory cells are capable of storing at least two bits per cell or two bits/one transistor with four multi-level threshold voltages (Vt0, Vt1, Vt2 and Vt03) in one physical cell. The multi-level threshold voltage programming of the one transistor NAND and NOR flash nonvolatile memory cells is referred to as multiple level programmed cells (MLC).

Currently, the highest-density of a single-chip double polycrystalline silicon gate NAND flash nonvolatile memory chip is 64 Gb. In contrast, a double polycrystalline silicon gate NOR flash nonvolatile memory chip has a density of 2 Gb. The big gap between NAND and NOR flash nonvolatile memory density is a result of the superior scalability of NAND flash nonvolatile memory cell over a NOR flash nonvolatile memory. A NOR flash nonvolatile memory cell requires 5.0V drain-to-source (Vds) to maintain a high-current Channel-Hot-Electron (CHE) injection programming process. Alternately, a NAND flash nonvolatile memory cell requires 0.0V between the drain to source for a low-current Fowler-Nordheim channel tunneling program process. The above results in the one-bit/one transistor NAND flash nonvolatile memory cell size being only one half that of a one-bit/one transistor NOR flash nonvolatile memory cell. This permits a NAND flash nonvolatile memory device to be used in applications that require huge data storage. A NOR flash nonvolatile memory device is extensively used as a program-code storage memory which requires less data storage and requires fast and asynchronous random access.

The act of programming of an N-channel Flash nonvolatile memory cell involves injecting the charge retaining region (floating gate or SONOS charge trapping layer) with electrons which causes the turn-on threshold voltage level of the memory cell to be increased. Thus, when programmed, an N-channel Flash nonvolatile memory cell will not turn on; that is, it will remain non-conductive, when addressed with a read is potential applied to its control gate. Alternately, the act of erasing a N-channel Flash nonvolatile memory cell involves removing electrons from the floating gate to lower the threshold voltage level. With the lower threshold voltage level, an N-channel Flash nonvolatile memory cell will turn on to a conductive state when addressed with a read potential to the control gate. However, the N-channel Flash nonvolatile memory cell suffers from the problem of over-erasure. Over-erasure occurs if, during the erasing step, too many electrons are removed from the floating gate leaving a slight positive charge. This biases the memory cell slightly on, so that a small current may leakage through the memory cell even when it is not addressed.

Currently, as discussed in U.S. Pat. No. 6,407,948 (Chou), the most commonly used Flash memory erasing methods employ the Fowler-Nordheim tunneling phenomena and the channel hot-electron tunneling phenomena. In an erasing operation for a Flash nonvolatile memory cell, a voltage is continually applied to a Flash nonvolatile memory cell to generate a voltage field with a negative potential difference between the control gate and the drain or channel of a Flash nonvolatile memory cell. Electrons accumulated in the floating gate of a Flash nonvolatile memory cell are reduced because the electrons pass through a thin dielectric layer of the Flash nonvolatile memory cell to cause a reduction of the threshold voltage of the Flash memory cell.

### SUMMARY OF THE INVENTION

An object of this invention is to provide a dual charge retaining (floating gate or SONOS) transistor NOR flash memory cell.

Another object of this invention is to provide a NOR flash memory cell for of an N-channel dual charge retaining transistor or P-channel dual charge retaining transistor.

Still another object of this invention is to provide methods and apparatus for erasing and programming of dual charge retaining transistor NOR flash memory cells to set a threshold voltage level of the erased dual charge retaining transistor NOR flash memory cells.

To accomplish at least one of these objects, an embodiment of a NOR flash memory cell is formed of dual serially connected charge retaining transistors. A drain/source of a first of the dual charge retaining transistors connected to a local bit line and a source/drain of a second of the dual charge retaining transistors connected to a local source line. The drain/sources of the commonly connected dual serially connected charge retaining transistors are connected solely together. The drain/sources and source drains are formed in a diffusion well. In some embodiments the diffusion well is formed in a deep diffusion well.

In some embodiments, the dual serially connected charge retaining transistors are N-channel charge retaining transistors. In other embodiments, the dual serially connected charge retaining transistors are P-channel charge retaining transistors. In still other embodiments, the N-channel charge retaining transistors are formed in a P-type well. In various embodiments, the P-type well is formed in deep N-type well that is formed in a P-type substrate. In various embodiments, the P-type well is formed in an N-type substrate. In still other embodiments, the P-channel charge retaining transistors are formed in an N-type well. In various embodiments, the N-type well is formed in deep P-type well that is formed in a N-type substrate. In various embodiments, the N-type well is formed in a P-type substrate.

In various embodiments, the dual serially connected charge retaining transistors each have a charge retaining layer that is formed of a charge storing polycrystalline floating gate layer or a metal layer. In other embodiments the dual serially connected charge retaining transistors each have a charge retaining layer that is formed of a charge trapping insulating layer where the charge trapping insulating layer is a silicon nitride.

In various embodiments, programming and erasing biasing voltages are applied to a control gate, a drain or source, and a bulk region of a selected charge retaining transistor of the dual serially connected charge retaining transistors to inject charge to or from the charge retaining layer to selectively program or erase the selected is charge retaining transistor of the serially connected charge retaining transistors. In some embodiments the selected charge retaining transistor of the serially connected charge retaining transistors is programmed by a combination of a band-to-band tunneling and a Fowler-Nordheim tunneling. In various embodiments, the selected charge retaining transistor of the serially connected charge retaining transistors is erased by a Fowler Nordheim tunneling.

In some embodiments, where the serially connected charge retaining transistors are N-channel floating gate transistors formed in a triple P-well in a deep N-well, the programming biasing voltages are a positive program voltage level (approximately 8V to approximately 12V) applied to the control gate, a drain/source program voltage level (approximately −6V) applied to the drain/source and source/drain of the serially connected charge retaining transistors, the negative triple well program voltage level (approximately −6V) applied to the triple P-well, and a well biasing voltage level that is the voltage level of the power supply voltage source (VDD) applied to the deep N-well. The erase biasing voltages are a negative erase voltage level (approximately −12V to approximately −8V) applied to the control gate and a positive well erase voltage level (approximately 5V to approximately 7V) applied to the triple P-well and the deep N-well and coupled to the drain/source and source/drain of the serially connected charge retaining transistors.

In other embodiments, where the serially connected charge retaining transistors are N-channel floating gate transistors formed in a triple P-well in a deep N-well, the threshold voltage levels representing erased serially connected charge retaining transistors and the threshold voltage level representing programmed serially connected charge retaining transistors are reversed. The programming biasing voltages are a negative programming voltage level (approximately −12V to approximately −8V) applied to the control gate, a positive drain/source programming voltage level (approximately 5V) applied to the drain/source and source/drain of the serially connected charge retaining transistors, a triple well program voltage level that is the ground reference voltage level applied to the triple P-well, and a deep well biasing is voltage that is the voltage level of the power supply voltage source (VDD) applied to the deep N-well. The erasing biasing voltages are a positive erase voltage level (approximately 8V to approximately 12V) applied to the control gate, a negative well erase voltage level (approximately −7V to approximately −5V) applied to the triple P-well and coupled to the drain/source and source/drain of the serially connected charge retaining transistors, and a deep well biasing voltage that the voltage level of the power supply voltage source applied to the deep N-well.

In still other embodiments where the serially connected charge retaining transistors are N-channel SONOS charge trapping transistors formed in a triple P-well in a deep N-well, the programming biasing voltages are a positive program voltage level (approximately 6V to approximately 8V) applied to the control gate, a negative drain/source program voltage level (−5V) applied to the drain/source and source/drain of the serially connected charge retaining transistors and to the triple P-well, and a deep well biasing voltage level that is the voltage level of the power supply voltage source applied to the deep N-well. The erasing biasing voltages are a negative erase voltage level (approximately −8V to approximately −6V) applied to the control gate, a positive well erase voltage level (approximately 4V to approximately 6V) applied to the triple P-well and to the deep N-well and coupled to the drain/source and source/drain of the serially connected charge retaining transistors.

In still other embodiments where the serially connected charge retaining transistors are N-channel SONOS charge trapping transistors formed in a triple P-well in a deep N-well, the threshold voltage levels representing erased serially connected charge retaining transistors and the threshold voltage level representing programmed serially connected charge retaining transistors are reversed. The programming biasing voltages are a negative program voltage level (approximately −7V to approximately −5V) to applied to the control gate, a positive drain/source program voltage level (5V) applied to the drain/source and source/drain of the serially connected charge retaining transistors, a triple well biasing voltage level that is the ground reference voltage level applied to the triple P-well, and a deep well biasing voltage level that is the voltage level of the power supply voltage source (VDD) applied to the deep N-well. The erasing biasing voltages are a positive erase voltage level (approximately 5V to approximately 7V) applied to the control gate, a negative triple well erase voltage level (approximately −7V to approximately −5V) applied to the triple P-well and coupled to the drain/source and source/drain of the serially connected charge retaining transistors, and a well biasing voltage level that is the voltage level of power supply voltage source (VDD) applied to the deep N-well.

In other embodiments, where the serially connected charge retaining transistors are P-channel floating gate transistors formed in an N-well, the programming biasing voltages are a positive program voltage level (approximately 8V to approximately 12V) applied to the control gate, a negative drain/source program voltage level (−5V) applied to the drain/source and source/drain of the serially connected charge retaining transistors, and a well biasing voltage level that is the ground reference voltage level applied to the N-well. The erasing biasing voltages are a large erase voltage level (approximately −12V to approximately −8V) applied to the control gate and a positive well biasing erase voltage level (approximately 7V to approximately 9V) applied to the N-well and coupled to the drain/source and source/drain of the serially connected charge retaining transistors.

In some embodiments, where the serially connected charge retaining transistors are P-channel floating gate transistors formed in a triple N-well in a deep P-well, the programming biasing voltages are a negative program voltage level (approximately −12V to approximately −8V) applied to the control gate, a positive drain/source erase voltage (approximately 6V) applied to the drain/source and source/drain of the serially connected charge retaining transistors and to the triple N-well, and a deep well biasing voltage that is the ground reference voltage (approximately 0V) applied to the deep P-well. The erase biasing voltages are a positive erase voltage level (approximately 8V to approximately (12V) applied to the control gate and a negative well erase voltage level (approximately −7V to approximately −5V) applied to the triple N-well and the deep P-well and coupled to the drain/source and source/drain of the serially connected charge retaining transistors.

In other embodiments, where the serially connected charge retaining transistors are P-channel floating gate transistors formed in a triple N-well in a deep P-well, the threshold voltage levels representing erased serially connected charge retaining transistors and the threshold voltage level representing programmed serially connected charge retaining transistors are reversed. The programming biasing voltages are a positive programming voltage level (approximately 8V to approximately 12V) applied to the control gate, a negative drain/source programming voltage level (approximately −5V) applied to the drain/source and source/drain of the serially connected charge retaining transistors, a triple well biasing voltage level that is the ground reference voltage level applied to the triple N-well, and the deep P-well. The erasing biasing voltages are a negative erase voltage level (approximately −12V to approximately −8V) applied to the control gate, a positive well erase voltage level (approximately 5V to approximately 7V) applied to the triple N-well and coupled to the drain/source and source/drain of the serially connected charge retaining transistors, and a deep well biasing voltage that is the ground reference voltage level applied to the deep P-well.

In other embodiments, where the serially connected charge retaining transistors are P-channel SONOS charge trapping transistors formed in an N-well, the programming biasing voltages are a positive program voltage level (approximately 5V to approximately 7V) applied to the control gate, a negative drain/source program voltage level (−6V) applied to the drain/source and source/drain of the serially connected charge retaining transistors, and a well biasing voltage level that is the ground reference voltage level applied to the N-well. The erasing biasing voltages are a negative erase voltage level (approximately −7V to approximately −5V) applied to the control gate and a positive erase well biasing voltage level (approximately 5V to approximately 7V) applied to the N-well and coupled to the drain/source and source/drain of the serially connected charge retaining transistors.

In some embodiments, where the serially connected charge retaining transistors are P-channel SONOS charge trapping transistors formed in a triple N-well in a deep P-well, the programming biasing voltages are a negative program voltage level (approximately −7V to approximately −5V) applied to the control gate, a positive drain/source erase voltage level (approximately 6V) applied to the drain/source and source/drain of the serially connected charge retaining transistors and to the triple N-well, and deep well biasing voltage level that is the ground reference voltage level (approximately 0V) applied to the deep P-well. The erase biasing voltages are a positive erase voltage level (approximately 5V to approximately (7V) applied to the control gate and a negative erase well biasing voltage level (approximately −7V to approximately −5V) applied to the triple N-well and the deep P-well and coupled to the drain/source and source/drain of the serially connected charge retaining transistors.

In other embodiments, where the serially connected charge retaining transistors are P-channel SONOS charge trapping transistors formed in a triple N-well in a deep P-well, the threshold voltage levels representing erased serially connected charge retaining transistors and the threshold voltage level representing programmed serially connected charge retaining transistors are reversed. The programming biasing voltages are a positive programming voltage level (approximately 5V to approximately 7V) applied to the control gate, a negative drain/source programming voltage level (approximately −6V) applied to the drain/source and source/drain of the serially connected charge retaining transistors, well biasing voltage level that is the ground reference voltage level applied to the triple N-well, and the deep P-well. The erasing biasing voltages are a negative erase voltage level (approximately −7V to approximately −5V) applied to the control gate, a positive triple well erase voltage level (approximately 5V to approximately 7V) applied to the triple N-well and coupled to the drain/source and source/drain of the serially connected charge retaining transistors, and a deep well biasing voltage level that is the ground reference voltage level applied to the deep P-well.

In various embodiments, a nonvolatile memory device has an array of NOR flash memory cells arranged in rows and columns. Each row of the array of NOR flash memory cells is associated with a pair of word lines. Each column of the array of NOR flash memory cells is associated with bit line and a source line. Each of the NOR flash memory cells is formed of dual serially connected charge retaining transistors. A drain/source of a first of the dual charge retaining transistors connected to a local bit line and a source/drain of a second of the dual charge retaining transistors connected to a local source line. The drain/sources of the commonly connected dual serially connected charge retaining transistors are connected solely together. The control gate of one charge retaining transistor of the dual serially connected charge retaining transistors is connected to one of the pair of word lines and the control gate of the other charge retaining transistor is connected to a second of the pair of word lines. The array of NOR flash memory cells is divided into sub-arrays that are placed in individual diffusion wells. In some embodiments the individual diffusion wells are further placed in deep diffusion wells formed in the surface of a substrate.

In some embodiments of the nonvolatile memory device, the dual serially connected charge retaining transistors are N-channel charge retaining transistors of each of the NOR flash memory cells within the array of NOR flash memory cells. In other embodiments of the nonvolatile memory device, the dual serially connected charge retaining transistors are P-channel charge retaining transistors. In still other embodiments of the nonvolatile memory device, the N-channel charge retaining transistors are formed in a P-type well. In various embodiments of the nonvolatile memory device, the P-type well is formed in deep N-type well that is formed in a P-type substrate. In other embodiments of the nonvolatile memory device, the P-type well is formed in an N-type substrate. In still other embodiments of the nonvolatile memory device, the P-channel charge retaining transistors are formed in an N-type well. In various embodiments of the nonvolatile memory device, the N-type well is formed in deep P-type well that is formed in an N-type substrate. In other embodiments of the nonvolatile memory device, the N-type well is formed in a P-type substrate.

In various embodiments of the nonvolatile memory device, the dual serially connected charge retaining transistors of each of the NOR flash memory cells each have a charge retaining layer that is formed of a charge storing polycrystalline floating gate layer or a metal layer. In other embodiments the dual serially connected charge retaining transistors each have a charge retaining layer that is formed of a charge trapping insulating layer where the charge trapping insulating layer is a silicon nitride.

In the various embodiments, the nonvolatile memory device includes a row voltage control circuit and a column voltage control circuit. The row voltage control circuit is connected to the word lines to provide necessary programming, erasing, and reading biasing voltages to control gates of the charge retaining transistors of the NOR flash memory cells for programming, erasing, and reading selected charge retaining transistors in the array of NOR flash memory cells. The column control circuit is communication with the bit lines and source lines of the columns of the NOR flash memory cells to provide the necessary programming, erasing, and reading biasing voltages to the drain/sources and source/drains of the NOR flash memory cells for programming, erasing, and reading the selected charge retaining transistors of the array of NOR flash memory cells. The row control circuit provides select signals for controlling the selection of the columns of NOR flash memory cells for the programming, erasing, and reading of the selected charge retaining transistors of the array of NOR flash memory cells. Further, the column control circuit is connected to provide the programming, erasing, and reading biasing voltages to the diffusion wells and the deep diffusion wells for the programming, erasing, and reading of the selected charge retaining transistors of the array of NOR flash memory cells.

In some embodiments of the nonvolatile memory device, where the serially connected charge retaining transistors are N-channel floating gate transistors formed in a triple P-well in a deep N-well, the programming biasing voltages are a positive program voltage level (approximately 8V to approximately 12V) applied to the control gate, a drain/source program voltage level (approximately −6V) applied to the drain/source and source/drain of the serially connected charge retaining transistors, the negative triple well program voltage level (approximately −6V) applied to the triple P-well, and a well biasing voltage level that is the voltage level of the power supply voltage source (VDD) applied to the deep N-well. The erase biasing voltages are a negative erase voltage level (approximately −12V to approximately −8V) applied to the control gate and a positive well erase voltage level (approximately 5V to approximately 7V) applied to the triple P-well and the deep N-well and coupled to the drain/source and is source/drain of the serially connected charge retaining transistors.

In some embodiments of the nonvolatile memory device, where the serially connected charge retaining transistors are N-channel floating gate transistors formed in a triple P-well in a deep N-well, the threshold voltage levels representing erased serially connected charge retaining transistors and the threshold voltage level representing programmed serially connected charge retaining transistors are reversed.

The programming biasing voltages are a negative programming voltage level (approximately −12V to approximately −8V) applied to the control gate, a positive drain/source programming voltage level (approximately 5V) applied to the drain/source and source/drain of the serially connected charge retaining transistors, a triple well program voltage level that is the ground reference voltage level applied to the triple P-well, and a deep well biasing voltage that is the voltage level of the power supply voltage source (VDD) applied to the deep N-well. The erasing biasing voltages are a positive erase voltage level (approximately 8V to approximately 12V) applied to the control gate, a negative well erase voltage level (approximately −7V to approximately −5V) applied to the triple P-well and coupled to the drain/source and source/drain of the serially connected charge retaining transistors, and a deep well biasing voltage that the voltage level of the power supply voltage source applied to the deep N-well.

In some embodiments of the nonvolatile memory device, where the serially connected charge retaining transistors are N-channel SONOS charge trapping transistors formed in a triple P-well in a deep N-well, the programming biasing voltages are a positive program voltage level (approximately 6V to approximately 8V) applied to the control gate, a negative drain/source program voltage level (−5V) applied to the drain/source and source/drain of the serially connected charge retaining transistors and to the triple P-well, and a deep well biasing voltage level that is the voltage level of the power supply voltage source applied to the deep N-well. The erasing biasing voltages are a negative erase voltage level (approximately −8V to approximately −6V) applied to the control gate, a positive well erase voltage level (approximately 4V to approximately 6V) applied to the triple P-well and to the deep N-well and coupled to the drain/source and source/drain of the serially connected charge retaining transistors.

In still other embodiments of the nonvolatile memory device, where the serially connected charge retaining transistors are N-channel SONOS charge trapping transistors formed in a triple P-well in a deep N-well, the threshold voltage levels representing erased serially connected charge retaining transistors and the threshold voltage level representing programmed serially connected charge retaining transistors are reversed. The programming biasing voltages are a negative program voltage level (approximately −7V to approximately −5V) applied to the control gate, a positive drain/source program voltage level (5V) applied to the drain/source and source/drain of the serially connected charge retaining transistors, a triple well biasing voltage level that is the ground reference voltage level applied to the triple P-well, and a deep well biasing voltage level that is the voltage level of the power supply voltage source (VDD) applied to the deep N-well. The erasing biasing voltages are a positive erase voltage level (approximately 5V to approximately 7V) applied to the control gate, a negative triple well erase voltage level (approximately −7V to approximately −5V) applied to the triple P-well and coupled to the drain/source and source/drain of the serially connected charge retaining transistors, and a well biasing voltage level that is the voltage level of power supply voltage source (VDD) applied to the deep N-well.

In some embodiments of the nonvolatile memory device, where the serially connected charge retaining transistors are P-channel floating gate transistors formed in an N-well, the programming biasing voltages are a positive program voltage level (approximately 8V to approximately 12V) applied to the control gate, a negative drain/source program voltage level (−5V) applied to the drain/source and source/drain of the serially connected charge retaining transistors, and a well biasing voltage level that is the ground reference voltage level applied to the N-well. The erasing biasing voltages are a large erase voltage level (approximately −12V to approximately −8V) applied to the control gate and a positive well biasing erase voltage level (approximately 7V to approximately 9V) applied to the N-well and coupled to the drain/source and source/drain of the serially connected charge retaining transistors.

In some embodiments of the nonvolatile memory device, where the is serially connected charge retaining transistors are P-channel floating gate transistors formed in a triple N-well in a deep P-well, the programming biasing voltages are a negative program voltage level (approximately −12V to approximately −8V) applied to the control gate, a positive drain/source erase voltage (approximately 6V) applied to the drain/source and source/drain of the serially connected charge retaining transistors and to the triple N-well, and a deep well biasing voltage that is the ground reference voltage (approximately 0V) applied to the deep P-well. The erase biasing voltages are a positive erase voltage level (approximately 8V to approximately (12V) applied to the control gate and a negative well erase voltage level (approximately −7V to approximately −5V) applied to the triple N-well and the deep P-well and coupled to the drain/source and source/drain of the serially connected charge retaining transistors.

In some embodiments of the nonvolatile memory device, where the serially connected charge retaining transistors are P-channel floating gate transistors formed in a triple N-well in a deep P-well, the threshold voltage levels representing erased serially connected charge retaining transistors and the threshold voltage level representing programmed serially connected charge retaining transistors are reversed. The programming biasing voltages are a positive programming voltage level (approximately 8V to approximately 12V) applied to the control gate, a negative drain/source programming voltage level (approximately −5V) applied to the drain/source and source/drain of the serially connected charge retaining transistors, a triple well biasing voltage level that is the ground reference voltage level applied to the triple N-well, and the deep P-well. The erasing biasing voltages are a negative erase voltage level (approximately −12V to approximately −8V) applied to the control gate, a positive well erase voltage level (approximately 5V to approximately 7V) applied to the triple N-well and coupled to the drain/source and source/drain of the serially connected charge retaining transistors, and a deep well biasing voltage that is the ground reference voltage level applied to the deep P-well.

In some embodiments of the nonvolatile memory device, where the serially connected charge retaining transistors are P-channel SONOS charge trapping is transistors formed in an N-well, the programming biasing voltages are a positive program voltage level (approximately 5V to approximately 7V) applied to the control gate, a negative drain/source program voltage level (−6V) applied to the drain/source and source/drain of the serially connected charge retaining transistors, and a well biasing voltage level that is the ground reference voltage level applied to the N-well. The erasing biasing voltages are a negative erase voltage level (approximately −7V to approximately −5V) applied to the control gate and a positive erase well biasing voltage level (approximately 5V to approximately 7V) applied to the N-well and coupled to the drain/source and source/drain of the serially connected charge retaining transistors.

In some embodiments of the nonvolatile memory device, where the serially connected charge retaining transistors are P-channel SONOS charge trapping transistors formed in a triple N-well in a deep P-well, the programming biasing voltages are a negative program voltage level (approximately −7V to approximately −5V) applied to the control gate, a positive drain/source erase voltage level (approximately 6V) applied to the drain/source and source/drain of the serially connected charge retaining transistors and to the triple N-well, and deep well biasing voltage level that is the ground reference voltage level (approximately 0V) applied to the deep P-well. The erase biasing voltages are a positive erase voltage level (approximately 5V to approximately (7V) applied to the control gate and a negative erase well biasing voltage level (approximately −7V to approximately −5V) applied to the triple N-well and the deep P-well and coupled to the drain/source and source/drain of the serially connected charge retaining transistors.

In some embodiments of the nonvolatile memory device, where the serially connected charge retaining transistors are P-channel SONOS charge trapping transistors formed in a triple N-well in a deep P-well, the threshold voltage levels to representing erased serially connected charge retaining transistors and the threshold voltage level representing programmed serially connected charge retaining transistors are reversed. The programming biasing voltages are a positive programming voltage level (approximately 5V to approximately 7V) applied to the control gate, a negative drain/source programming voltage level (approximately −6V) applied to the drain/source and source/drain of the serially connected charge retaining transistors, well biasing voltage level that is the ground reference voltage level applied to the triple N-well, and the deep P-well. The erasing biasing voltages are a negative erase voltage level (approximately −7V to approximately −5V) applied to the control gate, a positive triple well erase voltage level (approximately 5V to approximately 7V) applied to the triple N-well and coupled to the drain/source and source/drain of the serially connected charge retaining transistors, and a deep well biasing voltage level that is the ground reference voltage level applied to the deep P-well.

In other embodiments, a method of forming a NOR flash memory cell includes diffusing an impurity of a first conductivity type into a surface of a substrate to form three drain/source regions for dual charge retaining transistors. A first of the three drain/source regions is constructed as a drain for a first of the dual charge retaining transistors. A second of the drain/source regions is constructed as a source of a first of the dual charge retaining transistors and a drain of a second of a second of the dual charge retaining transistors to form the series connected dual charge retaining transistors. A third of the drain/source regions is constructed a source of the second charge retaining transistor. A thin oxide is formed over a bulk region between the first and second source/drain region and the second and third source/drain region. A charge retaining layer is formed over the oxide layer and a gate oxide layer is formed over the charge retaining layer of each of the charge retaining transistors. A control gate is formed over the gate oxide of each of the dual serially connected charge retaining transistors.

The drain of the first of the two series connected charge retaining transistors is connected to receive biasing voltages for programming, erasing, and reading the two series connected charge retaining transistors. Similarly, a source of the second of the two series connected charge retaining transistors is connected to receive biasing voltages for programming, erasing, and reading the two series connected charge retaining transistors. The commonly connected dual serially connected charge retaining transistors are connected solely together. The drain/sources and source drains are formed in a diffusion well. In some embodiments the diffusion well is formed is in a deep diffusion well.

In some embodiments, the dual serially connected charge retaining transistors are N-channel charge retaining transistors. In other embodiments, the dual serially connected charge retaining transistors are P-channel charge retaining transistors. In still other embodiments, the N-channel charge retaining transistors are formed in a P-type well. In various embodiments, the P-type well is formed in deep N-type well that is formed in a P-type substrate. In various embodiments, the P-type well is formed in an N-type substrate. In still other embodiments, the P-channel charge retaining transistors are formed in an N-type well. In various embodiments, the N-type well is formed in deep P-type well that is formed in a N-type substrate. In various embodiments, the N-type well is formed in a P-type substrate.

In various embodiments, the charge retaining layer of each of the dual serially connected charge retaining transistors is formed of a charge storing polycrystalline floating gate layer or a metal layer. In other embodiments, charge retaining layer of the dual serially connected charge retaining transistors is formed of a charge trapping insulating layer where the charge trapping insulating layer is a silicon nitride.

In other embodiments, a method for operating a two series connected charge retaining NOR flash memory cell includes applying programming and erasing biasing voltages to a control gate, a drain or source, and a bulk region of the charge retaining transistors of the NOR flash memory cell to inject charge to or from the charge retaining layer to selectively program or erase the selected charge retaining transistor of the serially connected charge retaining transistors. In some embodiments the selected charge retaining transistor of the serially connected charge retaining transistors is programmed by a combination of a band-to-band tunneling and a Fowler-Nordheim tunneling. In various embodiments, the selected charge retaining transistor of the serially connected charge retaining transistors is erased by a Fowler Nordheim tunneling.

In some embodiments, where the serially connected charge retaining transistors are N-channel floating gate transistors formed in a triple P-well in a deep N-well, the programming biasing voltages are a positive program voltage level (approximately 8V to approximately 12V) applied to the control gate, a drain/source program voltage level (approximately −6V) applied to the drain/source and source/drain of the serially connected charge retaining transistors, the negative triple well program voltage level (approximately −6V) applied to the triple P-well, and a well biasing voltage level that is the voltage level of the power supply voltage source (VDD) applied to the deep N-well. The erase biasing voltages are a negative erase voltage level (approximately −12V to approximately −8V) applied to the control gate and a positive well erase voltage level (approximately 5V to approximately 7V) applied to the triple P-well and the deep N-well and coupled to the drain/source and source/drain of the serially connected charge retaining transistors.

In other embodiments, where the serially connected charge retaining transistors are N-channel floating gate transistors formed in a triple P-well in a deep N-well, the threshold voltage levels representing erased serially connected charge retaining transistors and the threshold voltage level representing programmed serially connected charge retaining transistors are reversed. The programming biasing voltages are a negative programming voltage level (approximately −12V to approximately −8V) applied to the control gate, a positive drain/source programming voltage level (approximately 5V) applied to the drain/source and source/drain of the serially connected charge retaining transistors, a triple well program voltage level that is the ground reference voltage level applied to the triple P-well, and a deep well biasing voltage that is the voltage level of the power supply voltage source (VDD) applied to the deep N-well. The erasing biasing voltages are a positive erase voltage level (approximately 8V to approximately 12V) applied to the control gate, a negative well erase voltage level (approximately −7V to approximately −5V) applied to the triple P-well and coupled to the drain/source and source/drain of the serially connected charge retaining transistors, and a deep well biasing voltage that the voltage level of the power supply voltage source applied to the deep N-well.

In still other embodiments where the serially connected charge retaining transistors are N-channel SONOS charge trapping transistors formed in a triple P-well in a deep N-well, the programming biasing voltages are a positive program voltage level (approximately 6V to approximately 8V) applied to the control gate, a negative drain/source program voltage level (−5V) applied to the drain/source and source/drain of the serially connected charge retaining transistors and to the triple P-well, and a deep well biasing voltage level that is the voltage level of the power supply voltage source applied to the deep N-well. The erasing biasing voltages are a negative erase voltage level (approximately −8V to approximately −6V) applied to the control gate, a positive well erase voltage level (approximately 4V to approximately 6V) applied to the triple P-well and to the deep N-well and coupled to the drain/source and source/drain of the serially connected charge retaining transistors.

In still other embodiments where the serially connected charge retaining transistors are N-channel SONOS charge trapping transistors formed in a triple P-well in a deep N-well, the threshold voltage levels representing erased serially connected charge retaining transistors and the threshold voltage level representing programmed serially connected charge retaining transistors are reversed. The programming biasing voltages are a negative program voltage level (approximately −7V to approximately −5V) applied to the control gate, a positive drain/source program voltage level (5V) applied to the drain/source and source/drain of the serially connected charge retaining transistors, a triple well biasing voltage level that is the ground reference voltage level applied to the triple P-well, and a deep well biasing voltage level that is the voltage level of the power supply voltage source (VDD) applied to the deep N-well. The erasing biasing voltages are a positive erase voltage level (approximately 5V to approximately 7V) applied to the control gate, a negative triple well erase voltage level (approximately −7V to to approximately −5V) applied to the triple P-well and coupled to the drain/source and source/drain of the serially connected charge retaining transistors, and a well biasing voltage level that is the voltage level of power supply voltage source (VDD) applied to the deep N-well.

In other embodiments, where the serially connected charge retaining transistors are P-channel floating gate transistors formed in an N-well, the programming biasing voltages are a positive program voltage level (approximately 8V to approximately 12V) applied to the control gate, a negative drain/source program voltage level (−5V) applied to the drain/source and source/drain of the serially connected charge retaining transistors, and a well biasing voltage level that is the ground reference voltage level applied to the N-well. The erasing biasing voltages are a large erase voltage level (approximately −12V to approximately −8V) applied to the control gate and a positive well biasing erase voltage level (approximately 7V to approximately 9V) applied to the N-well and coupled to the drain/source and source/drain of the serially connected charge retaining transistors.

In some embodiments, where the serially connected charge retaining transistors are P-channel floating gate transistors formed in a triple N-well in a deep P-well, the programming biasing voltages are a negative program voltage level (approximately −12V to approximately −8V) applied to the control gate, a positive drain/source erase voltage (approximately 6V) applied to the drain/source and source/drain of the serially connected charge retaining transistors and to the triple N-well, and a deep well biasing voltage that is the ground reference voltage (approximately 0V) applied to the deep P-well. The erase biasing voltages are a positive erase voltage level (approximately 8V to approximately (12V) applied to the control gate and a negative well erase voltage level (approximately −7V to approximately −5V) applied to the triple N-well and the deep P-well and coupled to the drain/source and source/drain of the serially connected charge retaining transistors.

In other embodiments, where the serially connected charge retaining transistors are P-channel floating gate transistors formed in a triple N-well in a deep P-well, the threshold voltage levels representing erased serially connected charge to retaining transistors and the threshold voltage level representing programmed serially connected charge retaining transistors are reversed. The programming biasing voltages are a positive programming voltage level (approximately 8V to approximately 12V) applied to the control gate, a negative drain/source programming voltage level (approximately −5V) applied to the drain/source and source/drain of the serially connected charge retaining transistors, a triple well biasing voltage level that is the ground reference voltage level applied to the triple N-well, and the deep P-well. The erasing biasing voltages are a negative erase voltage level (approximately −12V to approximately −8V) applied to the control gate, a positive well erase voltage level (approximately 5V to approximately 7V) applied to the triple N-well and coupled to the drain/source and source/drain of the serially connected charge retaining transistors, and a deep well biasing voltage that is the ground reference voltage level applied to the deep P-well.

In other embodiments, where the serially connected charge retaining transistors are P-channel SONOS charge trapping transistors formed in an N-well, the programming biasing voltages are a positive program voltage level (approximately 5V to approximately 7V) applied to the control gate, a negative drain/source program voltage level (−6V) applied to the drain/source and source/drain of the serially connected charge retaining transistors, and a well biasing voltage level that is the ground reference voltage level applied to the N-well. The erasing biasing voltages are a negative erase voltage level (approximately −7V to approximately −5V) applied to the control gate and a positive erase well biasing voltage level (approximately 5V to approximately 7V) applied to the N-well and coupled to the drain/source and source/drain of the serially connected charge retaining transistors.

In some embodiments, where the serially connected charge retaining transistors are P-channel SONOS charge trapping transistors formed in a triple N-well in a deep P-well, the programming biasing voltages are a negative program voltage level (approximately −7V to approximately −5V) applied to the control gate, a positive drain/source erase voltage level (approximately 6V) applied to the drain/source and source/drain of the serially connected charge retaining transistors and to the triple N-well, and deep well biasing voltage level that is the ground reference voltage level (approximately 0V) applied to the deep P-well. The erase biasing voltages are a positive erase voltage level (approximately 5V to approximately (7V) applied to the control gate and a negative erase well biasing voltage level (approximately −7V to approximately −5V) applied to the triple N-well and the deep P-well and coupled to the drain/source and source/drain of the serially connected charge retaining transistors.

In other embodiments, where the serially connected charge retaining transistors are P-channel SONOS charge trapping transistors formed in a triple N-well in a deep P-well, the threshold voltage levels representing erased serially connected charge retaining transistors and the threshold voltage level representing programmed serially connected charge retaining transistors are reversed. The programming biasing voltages are a positive programming voltage level (approximately 5V to approximately 7V) applied to the control gate, a negative drain/source programming voltage level (approximately −6V) applied to the drain/source and source/drain of the serially connected charge retaining transistors, well biasing voltage level that is the ground reference voltage level applied to the triple N-well, and the deep P-well. The erasing biasing voltages are a negative erase voltage level (approximately −7V to approximately −5V) applied to the control gate, a positive triple well erase voltage level (approximately 5V to approximately 7V) applied to the triple N-well and coupled to the drain/source and source/drain of the serially connected charge retaining transistors, and a deep well biasing voltage level that is the ground reference voltage level applied to the deep P-well.

### BRIEF DESCRIPTION OF THE DRAWINGS

FIG. 1. is a cross sectional view of a charge retaining transistor.

FIG. 2a is schematic diagram of an embodiment of dual charge retaining N-channel transistor NOR flash memory cell embodying the principles of the present invention.

FIGS. 2b-1. 2b-2, 2c-1 and 2c-2 are top plan views and cross sectional cross sectional views of an embodiment of dual charge retaining N-channel transistor to NOR flash memory cell embodying the principles of the present invention.

FIGS. 2d and 2e are graphs of threshold voltage levels for various embodiments of the dual charge retaining N-channel transistor NOR flash memory cell embodying the principles of the present invention.

FIG. 3a is schematic diagram of an embodiment of dual charge retaining P-channel transistor NOR flash memory cell embodying the principles of the present invention.

FIGS. 3b-1, 3b-2, 3c-1, 3c-2, 3d-1, 3d-2, 3e-1, and 3e-2 are top plan views and cross sectional cross sectional views of various embodiments of dual charge retaining P-channel transistor NOR flash memory cells embodying the principles of the present invention.

FIGS. 3f and 3g are graphs of threshold voltage levels for a various embodiments of the dual charge retaining P-channel transistor NOR flash memory cell embodying the principles of the present invention.

FIG. 4 is a schematic diagram of a NOR flash nonvolatile memory device incorporating various embodiments of the dual charge retaining transistor NOR flash memory cell of the present invention.

FIG. 5 is a schematic diagram of row voltage control circuit of the NOR flash nonvolatile memory device of FIG. 4 embodying the principles of the present invention.

FIG. 6 is a schematic diagram of column voltage control circuit of the NOR flash nonvolatile memory device of FIG. 4 embodying the principles of the present invention.

FIGS. 7-16 are tables illustrating the voltage conditions for operating an array of an array of dual charge retaining transistor NOR flash memory cells for reading, erasing, erase verifying, programming, and program verifying selected dual charge retaining NOR flash memory cells embodying the principles of the present invention.

FIG. 17 is a flow chart of an erase operation for an array of dual charge is retaining transistor NOR flash memory cells embodying the principles of this invention.

FIG. 18 is a flow chart of an erase operation for a paired word line page of dual charge retaining transistor NOR flash memory cells within an array of dual charge retaining transistor NOR flash memory cells embodying the principles of this invention.

FIG. 19 is a flow chart of an erase operation for a block, sector, or an entire chip of an array of dual charge retaining transistor NOR flash memory cells embodying the principles of this invention.

FIG. 20 is a flow chart of an erase operation with preprogramming for a block, sector, or an entire chip of an array of dual charge retaining transistor NOR flash memory cells embodying the principles of this invention.

FIG. 21 is a flow chart of a read operation for dual charge retaining transistor NOR flash memory cells of an array of dual charge retaining transistor NOR flash memory cells embodying the principles of this invention.

FIG. 22 is a flow chart of a program operation for of a paired word line page of dual charge retaining transistor NOR flash memory cells of an array of dual charge retaining transistor NOR flash memory cells embodying the principles of this invention.

### DETAILED DESCRIPTION OF THE INVENTION

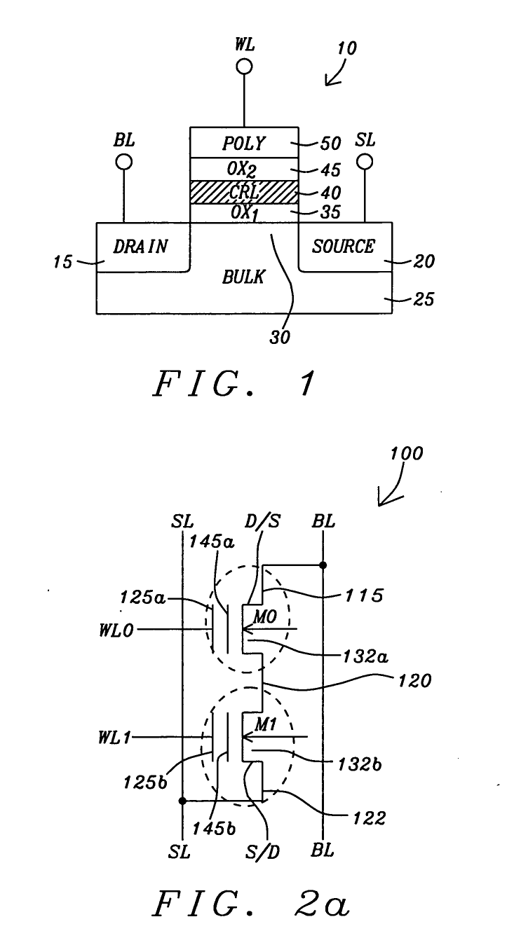

FIG. 1 is a cross sectional view of a flash charge retaining transistor 10. A charge retaining flash cell 10 is formed in the top surface of a bulk region 25. An impurity material of a first type is diffused into the surface of the bulk region 25 to form a drain region 15 and a source region 20. A tunnel oxide 35 is formed on top of a channel region 30 between the drain region 15 and the source region 20. The thickness of the tunnel oxide 35 is typically 100 Å. The tunnel oxide 35 is the layer through which the is electron charges tunnel during the programming or erasing. A charge retaining layer 40 is formed above the channel region 30 of the bulk region 25 between the drain region 15 and the source region 20. An interlayer insulating oxide layer 45 is formed on the charge retaining layer 45 to electrically isolate or float the charge retaining layer 40. A conductive layer of a metal or doped polycrystalline silicon is formed over the interlayer insulating oxide layer 45 to create a control gate 50 of the flash charge retaining transistor 10. The gate length flash charge retaining transistor 10 is the length of channel region 30 between drain region 15 and the source region 20. The flash charge retaining transistor's 10 channel width is determined by the width of the N-diffusion of the drain 15 and the source 20. The typical unit size of the flash charge retaining transistors 10 is about 4λ² with 2λ in X-dimension and 2λ in Y-dimension. The dimension Lambda (λ) is the minimum size of feature geometry achievable within a manufacturing process.

In some embodiments, the bulk region 25 is formed by diffusing an impurity material of a second conductivity type into a substrate having been doped with the impurity of the first conductivity type. This forms a single well structure for the flash charge retaining transistors. In other embodiments, the bulk region 25 is formed by diffusing an impurity material of the second conductivity type into a deep well. The bulk region 25 thus forming what is commonly termed as a triple well The deep well having been formed by diffusing the impurity of the first conductivity type into a substrate that has been doped with the impurity of the second conductivity type.

In a traditional operation, the flash charge retaining transistor 10 is to programmed and erased attracting or expelling stored charges from the charge retaining layer 40 through the tunnel oxide 35 to cell's channel region 30 or to the drain region 15 and/or the source region 20. The phenomenon for the attracting and expelling of the stored charges is either band-to-band hot-electron tunneling, or Fowler-Nordheim tunneling, or a combination of the two phenomena.

In various embodiments, the charge retaining layer 40 is polycrystalline silicon or metal that forms a floating gate. In other embodiments, the charge retaining layer 40 is an insulating material such as a silicon nitride to form a charge trapping layer.

In some embodiments, the impurity material of the first conductivity type is a P-type material and the material of the second conductivity type is an N-type material.

In other embodiments, the impurity material of the first conductivity type is an N-type material and the material of the second conductivity type is a P-type material.

In embodiments where the drain region 15 and the source region 20 are formed to be a P-type material and the bulk region 25 is an N-type material forming a single well, the charge retaining layer of the P-channel the flash charge retaining transistor 10 is erased by biasing the control gate to a positive erase voltage level of approximately 10V, the drain region 15 to a negative erase voltage level of approximately −8V, and the source region 20 to be floating. These voltage levels cause a depletion layer to form at the junction between the drain region 15 and the bulk region 25. As described in U.S. Pat. No. 5,877,524 (Oonakado, et al.) these biasing conditions for a P-channel flash charge retaining transistor 10 memory cell utilizes a combination of Fowler-Nordheim tunneling and band-to-band tunneling induced electron injection to the charge retaining layer 40. A strong vertical field between the control gate 50 and the drain region 15 of the P-channel flash charge retaining transistor 10 memory cell generates electron-hole pairs. The generated band-to-band tunneling electrons are accelerated in the depletion layer controlled by the junction electron field between a negatively biased drain region 15 and the bulk region 25 that is connected to a ground reference voltage level. The Fowler-Nordheim tunneling occurs at the overlap region between drain region 15 side and the charge retaining layer 40 of the P-channel flash charge retaining transistor 10 memory cell. The combination of the band-to-band tunneling and the Fowler-Nordheim tunneling causes more electrons to be injected to the charge retaining layer 40 to lower the threshold voltage (absolute value).

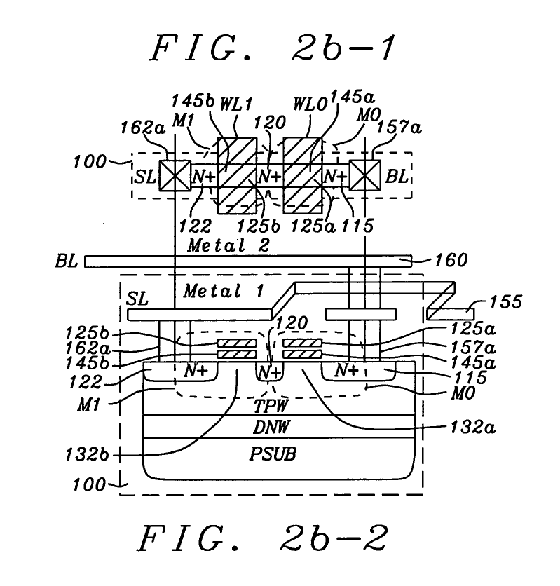

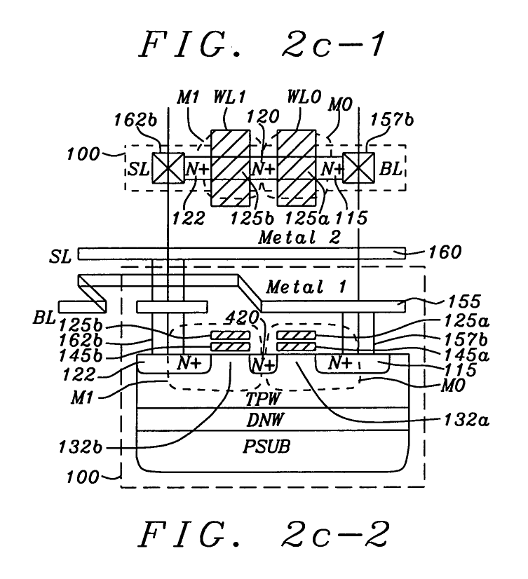

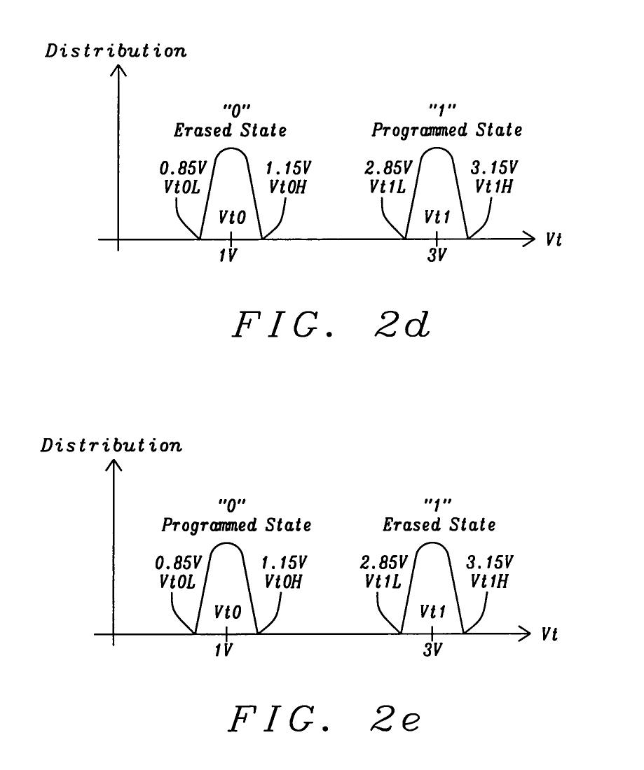

FIG. 2a is the schematic diagram of a NAND-like dual charge retaining N-Channel transistor NOR flash memory cell 100. FIGS. 2b-1 and 2c-1 are top plan views of implementations of a dual charge retaining transistor NOR flash memory cell 100. FIGS. 2b-2 and 2c-2 are cross sectional views of implementations of a dual charge retaining transistor NOR flash memory cell 100. The dual charge retaining transistor NOR flash cell 100 is formed in the top surface of a P-type substrate PSUB. An N-type material is diffused into the surface of the P-type substrate PSUB to form a deep N-type diffusion well DNW. A P-type material is then diffused into the surface of the deep N-type diffusion well DNW to form a shallow P-type diffusion well TPW (commonly referred to as a triple P-well). The N-type material is then diffused into the surface of the shallow P-type diffusion well TPW to form the drain/source region (D/S) 115 of the charge retaining transistor M0, the source/drain region (S/D) 122 of the charge retaining transistor M1 and the common source/drain (S/D) 120. The common source/drain 120 being the source region of the charge retaining transistor M0 and the drain of the charge retaining transistors M1. The common source/drain 120 for the charge retaining transistors M0 and M1 solely connects the source of the charge retaining transistor M0 and the drain of the charge retaining transistor M1 with no other external connections.

A tunnel oxide is formed on top of the channel region 132a and 132b between the drain/source region 115 and the common source/drain region 120 of the charge retaining transistor M0 and between the common source/drain region 120 and the source/drain region 122 of the charge retaining transistor M1 and beneath the charge retaining layers 145a and 145b. The thickness of the tunnel oxide is typically 100 Å. The tunnel oxide is the layer through which the electron charges pass during the Fowler-Nordheim channel tunneling for the programming and erasing. During a programming operation, the Fowler-Nordheim tunnel programming attracts electrons to the charge retaining layers 145a and 145b through the tunnel oxide from cell's channel regions 132a and 132b within the shallow P-type diffusion well TPW. During an erasing operation, the Fowler-Nordheim tunnel erasing expels stored electrons from the charge retaining layers 145a and 145b through the tunnel oxide to cell's channel regions 132a and 132b and thus into the shallow P-type diffusion well TPW.

In some embodiments, a first polycrystalline silicon layer is formed above the bulk regions 132a and 132b of the shallow P-type diffusion well TPW between the drain/source region 115 and the common source/drain region 120 charge retaining transistor M0 and the common source/drain region 120 and the source/drain region 122 of the charge retaining transistor M1 to form the charge retaining layers 145a and 145b as floating gates. In some embodiments, an insulating layer such as a silicon nitride is formed above the bulk regions 132a and 132b of the shallow P-type diffusion well TPW between the drain/source region 115 and the common source/drain region 120 charge retaining transistor M0 and the common source/drain region 120 and the source/drain region 122 of the charge retaining transistor M1 to form the charge retaining layers 145a and 145b as SONOS charge trapping layers.

A polycrystalline silicon layer is formed over an insulating oxide layer (45 of FIG. 1) above the charge retaining layers 145a and 145b to create the control gates (G) 125a and 125b of the charge retaining transistors M0 and M1. The common source/drain region 120 is formed as self-aligned between the two adjacent second polycrystalline silicon layers of two control gates 125a and 125b of charge retaining transistors M0 and M1. The common source/drain 120 is used in the charge retaining transistors M0 and M1 to reduce the source line pitch.

The gate length of the charge retaining transistors M0 and M1 is the channel region 132a and 132b in the bulk region of shallow P-type well TPW between drain/source region 115 and the common source/drain region 120 of the charge retaining transistor M0 and the common source/drain region 120 and the source/drain region 122 of the charge retaining transistors M0 and M1. The NOR charge retaining transistor's channel M0 and M1 width is determined by the width of the N-diffusion of the drain/source region 115, the source/drain region 122 and the common source/drain to region 120. The typical unit size of the dual charge retaining transistor NOR flash memory cell 100 is approximately 12λ². Therefore the effective size for a single bit NOR cell is approximately 6λ². The effective size (6λ²) of a single bit NOR cell is slightly larger than a NAND cell size of the prior art. However, the effective size of a single bit NOR cell is much smaller than the NOR cell size (10λ²) of the prior art for a semiconductor manufacturing process above 50 nm. The NOR cell structure of the prior art is projected to increase to 15λ² due to the scalability issues in semiconductor manufacturing process below 50 nm. The effective single bit/single transistor size of the dual charge retaining transistor NOR flash memory cell 100 remains constant an effective cell size of approximately 6λ². The constant cell size is a result of the scalability is identical to that of the NAND flash memory cell of the prior art.

The charge retaining layers 145a and 145b each respectively store electron charges to modify the threshold voltage of the charge retaining transistors M0 and M1. In all operations such as read, program and erase, the P-type substrate PSUB is always connected to a ground reference voltage source (GND). The deep N-type diffusion well DNW is connected to the power supply voltage source (VDD) in read and program operations but is connected to an erase voltage or the power supply voltage source in a Fowler-Nordheim channel erase operation. The shallow P-type well TPW is connected to the ground reference voltage in normal read operations. In program operations, the shallow P-type well TPW is connected to a program voltage or the ground reference power supply. The shallow P-type well TPW is connected to the erase voltage in the Fowler Nordheim channel erase operation. The deep n-type p-well DNW and the shallow P-type diffusion well TPW are biased commonly to the erase voltage level to avoid the undesired forward current. In present designs of dual charge retaining transistor NOR flash memory cell 100, the power supply voltage source is either 1.8V or 3.0V.

In an array of dual charge retaining transistor NOR flash memory cells 100, the charge retaining transistors M0 and M1 are arranged in rows and columns. The polycrystalline silicon layer that is the control gate 125 of the charge retaining transistors M0 and M1 and is extended to form a word-line WL that connects to each of the charge retaining transistors M0 and M1 on a row of the array. The drain/source 115 of the charge retaining transistors M0 and M1 is connected to a bit line BL. The source/drain 122 of the charge retaining transistor M1 is connected to a source line SL. The bit line BL and the source line SL being formed in parallel and in parallel with a column of the charge retaining transistors M0 and M1. The bit lines BL and the source is lines SL are formed as either first level metal 155 or second level metal 160 of FIGS. 2b-2 and 2c-2. The bit lines BL are connected respectively through the vias 157a and 157b to the drain 115 of the charge retaining transistors M0. The source lines SL are connected respectively through the vias 162a and 162b to the source 122 of the floating-gate transistor M1.

Refer now to FIG. 2d for a discussion of the threshold voltage levels for a single level programming of the dual charge retaining transistor NOR flash memory cell 100 where the charge retaining layers 145a and 145b are floating gates or SONOS charge trapping layers. The erased state illustrates the distribution of the two charge retaining transistors M0 and M1 that have their threshold voltage levels reduced to a voltage level less than an upper voltage limit of a erased state Vt0H or approximately +1.15V. If the two charge retaining transistors M0 and M1 have their threshold voltage less than the lower voltage limit VT0L of approximately +0.85V, they may be in a marginally conductive state during a read operation which may cause corruption of the data during a read operation due to the leakage current. To prevent this, the two charge retaining transistors M0 and M1 have two positive erased states (Vt0 for the erase state “0” and Vt1 for the programmed state “1”). The erased state Vt0 that is nominally +1.0V with a lower voltage limit VT0L of approximately +0.85V and an upper voltage limit Vt0H of approximately +1.15V and a programmed state Vt1 that is nominally +3.0V with a lower voltage limit VT1L of approximately +2.85V and an upper voltage limit Vt1H of approximately +3.15V. A selected one of the two charge retaining transistors M0 and M1 is erased such that the threshold voltage level is forced to be less than the upper voltage limit of a erased state Vt0H. In some embodiments, the selected one of the two charge retaining transistors M0 and M1 is then over-erase verified to determine that its threshold voltage is greater than the lower voltage limit of the erased state Vt0L. If the threshold voltage is less than the lower voltage limit of the erased state Vt0L, the selected one of the two charge retaining transistors M0 and M1 is then programmed to bring the threshold voltage level to be greater than the lower voltage limit of the erased state Vt0L. After the programming, the selected one of the two charge retaining transistors M0 and M1, it is again over-erase verified to ensure that the threshold voltage level of the selected one of the two charge retaining transistors M0 and M1 is greater than the lower voltage limit Vt0L of the erased state.

In some embodiments, when the selected one of the two charge retaining transistors M0 and M1 is to be programmed, the selected charge retaining transistor M0 or M1 is first erased as described and then reprogrammed to be within the lower Vt0L and upper Vt0H limits of the erased state Vt0. If the selected one of the two charge retaining transistor M0 or M1 is to be programmed to a programmed state Vt1, the selected charge retaining transistor M0 or M1 is programmed to the programmed state Vt1. The selected charge retaining transistor M0 or M1 is then program verified that its threshold voltage level is greater than the lower voltage limit of the programmed state Vt1L.

Refer now to FIG. 2e for a discussion of the threshold voltage levels for a single level programming of the dual charge retaining transistor NOR flash memory cell 100 where the charge retaining layers 145a and 145b are floating gates. FIG. 2e illustrates an alternate process where the erase and program threshold voltage levels are reversed from those of FIG. 2d. The erased state illustrates the distribution of the two charge retaining transistors M0 and M1 that have their threshold voltage levels increased to a voltage level greater than a lower voltage limit of a erased state Vt1L or approximately +2.85V. The erased state Vt1 that is nominally +3.0V with a lower voltage limit VT1L of approximately +2.85V and an upper voltage limit Vt1H of approximately +3.15V and a programmed state Vt0 that is nominally +1.0V with a lower voltage limit VT0L of approximately +0.85V and an upper voltage limit Vt0H of approximately +1.15V. A selected one of the two charge retaining transistors M0 and M1 is erased such that the threshold voltage level is forced to be greater than the lower voltage limit of a erased state Vt1L. In some embodiments, the selected one of the two charge retaining transistors M0 and M1 is then erase verified to determine that its threshold voltage is greater than the lower voltage limit of the erased state Vt1L. If the threshold voltage is less than the lower voltage limit of the erased state Vt1L, the selected one of the two charge retaining transistors M0 and M1 is then programmed to bring the threshold voltage level to be greater than the lower voltage limit of the erased is state Vt1L. After the programming, the selected one of the two charge retaining transistors M0 and M1, it is again erase verified to ensure that the threshold voltage level of the selected one of the two charge retaining transistors M0 and M1 is greater than the lower voltage limit Vt1L of the erased state.

In some embodiments, when the selected one of the two charge retaining transistors M0 and M1 is to be programmed, the selected charge retaining transistor M0 or M1 is programmed to the programmed state Vt0. The selected charge retaining transistor M0 or M1 is then program verified that its threshold voltage level is greater than the lower voltage limit of the programmed state Vt0L and less than the upper limit of the programmed state Vt0H.

FIG. 3a is the schematic diagram of a NAND-like dual charge retaining P-channel transistor NOR flash memory cell 200. FIGS. 3b-1, 3c-1, 3d-1 and 3e-1 are top plan views of implementations of a dual charge retaining transistor NOR flash memory cell 200. FIGS. 3b-2, 3c-2, 3d-2 and 3e-2 are cross sectional views of implementations of a dual charge retaining transistor NOR flash memory cell 200.

In various embodiments as shown in FIGS. 3b-1, 3b-2, 3c-1, and 3c-2, the dual charge retaining transistor NOR flash cell 200 is formed in the top surface of a P-type substrate PSUB. An N-type material is diffused into the surface of the P-type substrate PSUB to form a N-type diffusion well N-WELL. The P-type material is then diffused into the surface of the N-type diffusion well N-WELL to form the drain/source region (D/S) 215 of the charge retaining transistor M0, the source/drain region (S/D) 222 of the charge retaining transistor M1 and the common source/drain (S/D) 220. The common source/drain 220 being the source region of the charge retaining transistor M0 and the drain of the charge retaining transistors M1. The common source/drain 220 for to the charge retaining transistors M0 and M1 solely connects the source of the charge retaining transistor M0 and the drain of the charge retaining transistor M1 with no other external connections.

In other embodiments as shown in FIGS. 3d-1, 3d-2, 3e-1, and 3e-2, the dual charge retaining transistor NOR flash cell 200 is formed in the top surface of an N-type substrate NSUB. A P-type material is diffused into the surface of the N-type substrate NSUB to form a deep P-type diffusion well DPW. An N-type material is then diffused into the surface of the deep P-type diffusion well DPW to form a shallow N-type diffusion well TNW (commonly referred to as a triple N-well). The P-type material is then diffused into the surface of the shallow N-type diffusion well TNW to form the drain/source region (D/S) 215 of the charge retaining transistor M0, the source/drain region (S/D) 222 of the charge retaining transistor M1 and the common source/drain (S/D) 220. The common source/drain 220 being the source region of the charge retaining transistor M0 and the drain of the charge retaining transistors M1. The common source/drain 220 for the charge retaining transistors M0 and M1 solely connects the source of the charge retaining transistor M0 and the drain of the charge retaining transistor M1 with no other external connections.

A tunnel oxide is formed on top of the channel region 232a and 232b between the drain/source region 215 and the common source/drain region 220 of the charge retaining transistor M0 and between the common source/drain region 220 and the source/drain region 222 of the charge retaining transistor M1 and beneath the charge retaining layers 245a and 245b. The thickness of the tunnel oxide is typically 100 Å. The tunnel oxide is the layer through which the electron charges pass during the Fowler-Nordheim channel tunneling and the band-to-band hot carrier tunneling for the programming and erasing. During a programming operation, the combination of band to band tunneling and Fowler-Nordheim tunnel programming attracts electrons to the charge retaining layers 245a and 245b through the tunnel oxide from cell's channel regions 232a and 232b within the shallow P-type diffusion well N-WELL. During an erasing operation, the Fowler-Nordheim tunnel erasing expels stored electrons from the charge retaining layers 245a and 245b through the tunnel oxide to cell's drain source regions 215 and 222 and thus into the shallow P-type diffusion well N-WELL.

In some embodiments, a first polycrystalline silicon layer is formed above the bulk regions 232a and 232b of the shallow P-type diffusion well N-WELL between the drain/source region 215 and the common source/drain region 220 charge retaining transistor M0 and the common source/drain region 220 and the source/drain region 222 of the charge retaining transistor M1 to form the charge retaining layers 245a and 245b as floating gates. In some embodiments, an insulating layer such as a silicon nitride is formed above the bulk regions 232a and 232b of the shallow P-type diffusion well N-WELL between the drain/source region 215 and the common source/drain region 220 charge retaining transistor M0 and the common source/drain region 220 and the source/drain region 222 of the charge retaining transistor M1 to form the charge retaining layers 245a and 245b as SONOS charge trapping layers.

A polycrystalline silicon layer is formed over an insulating oxide layer (45 of FIG. 1) above the charge retaining layers 245a and 245b to create the control gates (G) 225a and 225b of the charge retaining transistors M0 and M1. The common source/drain region 220 is formed as self-aligned between the two adjacent second polycrystalline silicon layers of two control gates 225a and 225b of charge retaining transistors M0 and M1. The common source/drain 220 is used in the charge retaining transistors M0 and M1 to reduce the source line pitch.

The gate length of the charge retaining transistors M0 and M1 is the channel region 232a and 232b in the bulk region of N-type well N-WELL between drain/source region 215 and the common source/drain region 220 of the charge retaining transistor M0 and the common source/drain region 220 and the source/drain region 222 of the charge retaining transistors M0 and M1. The NOR charge retaining transistor's channel M0 and M1 width is determined by the width of the N-diffusion of the drain/source region 215, the source/drain region 222 and the common source/drain region 220.

The charge retaining layers 245a and 245b each respectively store electron charges to modify the threshold voltage of the charge retaining transistors M0 and M1. In all operations such as read, program and erase, the P-type substrate PSUB is always connected to a ground reference voltage source (GND). The deep N-type diffusion well N-WELL is connected to the power supply voltage source (VDD) in read and program operations but is connected to an erase voltage or the power supply is voltage source in a Fowler-Nordheim channel erase operation. The N-type well N-WELL is connected to the ground reference voltage in normal read operations. In program operations, the N-type well N-WELL is connected to a program voltage or the ground reference power supply. The N-type well N-WELL is connected to the erase voltage in the Fowler Nordheim channel erase operation. The deep n-type p-well N-WELL and the shallow P-type diffusion well N-WELL are biased commonly to the erase voltage level to avoid the undesired forward current. In present designs of dual charge retaining transistor NOR flash memory cell 200, the power supply voltage source is either 1.8V or 3.0V.

In an array of dual charge retaining transistor NOR flash memory cells 200, the charge retaining transistors M0 and M1 are arranged in rows and columns. The polycrystalline silicon layer that is the control gate 225 of the charge retaining transistors M0 and M1 and is extended to form a word-line WL that connects to each of the charge retaining transistors M0 and M1 on a row of the array. The drain/source 215 of the charge retaining transistors M0 and M1 is connected to a bit line BL. The source/drain 222 of the charge retaining transistor M1 is connected to a source line SL. The bit line BL and the source line SL being formed in parallel and in parallel with a column of the charge retaining transistors M0 and M1. The bit lines BL and the source lines SL are formed as either first level metal 255 or second level metal 260 of FIGS. 2b-2 and 2c-2. The bit lines BL are connected respectively through the vias 257a and 257b to the drain 215 of the charge retaining transistors M0. The source lines SL are connected respectively through the vias 262a and 262b to the source 222 of the floating-gate transistor M1.

Refer now to FIG. 3f for a discussion of the threshold voltage levels for a single level programming of the dual charge retaining transistor NOR flash memory cell 200 where the charge retaining layers 245a and 245b are either floating gates or SONOS charge trapping layers. In the erased state as illustrated, the distribution of the two charge retaining transistors M0 and M1 have their threshold voltage levels reduced to a voltage level less than an upper voltage limit of a erased state Vt1H or approximately −2.85V. In the program state as illustrated, the distribution of the two charge retaining transistors M0 and M1 have their threshold voltage levels reduced to a voltage level greater than a lower voltage limit of a erased state Vt0L or approximately −1.15V. The erased state Vt1 is nominally −3.0V with a lower voltage limit VT1L of approximately −3.15V and an upper voltage limit Vt1H of approximately −2.85V and a programmed state Vt0 is nominally −1.0V with a lower voltage limit VT0L of approximately −1.15V and an upper voltage limit Vt0H of approximately −0.85V. A selected one of the two charge retaining transistors M0 and M1 is erased such that the threshold voltage level is forced to be less than the upper voltage limit of a erased state Vt1H.

In some embodiments, the selected one of the two charge retaining transistors M0 and M1 is then erase verified to determine that its threshold voltage is less than the upper voltage limit of the erased state Vt1H. If the threshold voltage is less than the lower voltage limit of the erased state Vt1L, the selected one of the two charge retaining transistors M0 and M1 is then programmed to bring the threshold voltage level to be greater than the lower voltage limit of the erased state Vt1L. After the programming, the selected one of the two charge retaining transistors M0 and M1, it is again erase verified to ensure that the threshold voltage level of the selected one of the two charge retaining transistors M0 and M1 is greater than the lower voltage limit Vt1L of the erased state.

In some embodiments, when the selected one of the two charge retaining transistors M0 and M1 is to be programmed, the selected charge retaining transistor M0 or M1 is first erased as described and then reprogrammed to be within the lower Vt0L and upper Vt0H limits of the program state Vt0. If the selected one of the two charge retaining transistor M0 or M1 is to be programmed to a programmed state Vt0, the selected charge retaining transistor M0 or M1 is programmed to the programmed state Vt0. The selected charge retaining transistor M0 or M1 is then program verified that its threshold voltage level is greater than the lower voltage limit of the programmed state Vt0L.

Refer now to FIG. 3g for a discussion of the threshold voltage levels for a single level programming of the dual charge retaining transistor NOR flash memory cell 200 where the charge retaining layers 245a and 245b are either floating gates or SONOS charge trapping layers. FIG. 3g illustrates an alternate process where the erase and program threshold voltage levels are reversed from those of FIG. 3f. In the erased state as illustrated, the distribution of the two charge retaining transistors M0 and M1 have their threshold voltage levels reduced to a voltage level greater than a lower voltage limit of a erased state Vt0L or approximately −1.15V. In the programmed state as illustrated, the distribution of the two charge retaining transistors M0 and M1 that have their threshold voltage levels reduced to a voltage level less than an upper voltage limit of a programmed state Vt1H or approximately −2.85V. The erased state Vt0 is nominally −1.0V with an upper voltage limit VT0H of approximately −0.85V and a lower voltage limit Vt0L of approximately −1.15V and a programmed state Vt1 is nominally −3.0V with a lower voltage limit VT0L of approximately −1.15V and an upper voltage limit Vt0H of approximately −0.85V.

A selected one of the two charge retaining transistors M0 and M1 is erased such that the threshold voltage level is forced to be greater than the lower voltage limit of an erased state Vt0L. In some embodiments, the selected one of the two charge retaining transistors M0 and M1 is then erase verified to determine that its threshold voltage is greater than the lower voltage limit of the erased state Vt0L. If the threshold voltage is greater than the upper voltage limit of the erased state Vt0H, the selected one of the two charge retaining transistors M0 and M1 is then programmed to bring the threshold voltage level to be less than the upper voltage limit of the erased state Vt0H. After the programming, the selected one of the two charge retaining transistors M0 and M1, it is again erase verified to ensure that the threshold voltage level of the selected one of the two charge retaining transistors M0 and M1 is less than to the upper voltage limit Vt0H of the erased state.

In some embodiments, when the selected one of the two charge retaining transistors M0 and M1 is to be programmed, the selected charge retaining transistor M0 or M1 is first erased as described and then reprogrammed to be within the lower Vt1L and upper Vt1H limits of the program state Vt1. If the selected one of the two charge is retaining transistor M0 or M1 is to be programmed to a programmed state Vt1, the selected charge retaining transistor M0 or M1 is programmed to the programmed state Vt1. The selected charge retaining transistor M0 or M1 is then program verified that its threshold voltage level is less than the upper voltage limit of the programmed state Vt1H.

FIG. 4 is a schematic diagram of a NOR flash nonvolatile memory device 300 incorporating the NAND-like dual charge retaining transistor NOR flash cell 310 embodying the principles of the present invention. The NOR flash nonvolatile memory device 300 includes an array 305 of dual charge retaining transistor NOR flash cells 310 arranged in a matrix of rows and columns. Each of the dual charge retaining transistor NOR flash cells 310 includes two charge retaining transistors M0 and M1. The two charge retaining transistors M0 and M1 are structured and operate as the charge retaining transistors M0 and M1 described above in FIGS. 2a, 2b-1, 2b-2, 2c-1, 2c-2, 2a, 3b-1, 3b-2, 3c-1, 3c-2, 3d-1, 3d-2, 3e-1, and 3e-2. The drain of the charge retaining transistor M0 is connected to one of the local metal bit lines LBL0, LBL1, . . . , LBLn−1, and LBLn. The source of the charge retaining transistor M1 is connected of one of the local metal source lines LSL0, LSL1, . . . , LSLn−1, and LSLn. The source of the charge retaining transistor M0 is connected to the drain of the NOR charge retaining transistor M1. Each of the local bit lines LBL0, LBL1, . . . , LBLn−1, and LBLn and the local source lines LSL0, LSL1, . . . , LSLn−1, and LSLn are arranged in parallel with a column of the array 305 of dual charge retaining transistor NOR flash cells 310, The local bit lines LBL0, LBL1, . . . , LBLn−1, and LBLn and the local source lines LSL0, LSL1, . . . , LSLn−1, and LSLn are connected to the dual charge retaining transistor NOR flash cells 310 such that the dual charge retaining transistor NOR flash cells 310 are symmetrical. The local bit lines LBL0, LBL1, . . . , LBLn−1, and LBLn and the local source lines LSL0, LSL1, . . . , LSLn−1, and LSLn may be biased interchangeably to operate the array 305 of dual charge retaining transistor NOR flash cells 310.

The local metal bit lines LBL0, LBL1, . . . , LBLn−1, and LBLn associated with adjacent columns of the dual charge retaining transistor NOR flash cells 310 are connected through the bit line select transistors 360a, . . . , 360n to the global metal bit is lines GBL0, . . . , GBLn. The local metal source lines LSL0, LSL1, . . . , LSLn−1, and LSLn associated with adjacent columns of the dual charge retaining transistor NOR flash cells 310 are connected through the source line select transistors 365a, . . . , 365n to the global source lines GSL0, . . . , GSLn. The global bit lines GBL0, . . . . , GBLn and the global source lines GSL0, . . . , GSLn are connected to the column voltage control circuit 355. The column voltage control circuit 355 generates the appropriate voltage levels for selectively reading, programming, and erasing the dual charge retaining transistor NOR flash cells 310.

Each of the control gates of the charge retaining transistors M0 and M1 of the dual charge retaining transistor NOR flash cells 310 on each row of the array 305 is connected to one of the word lines WL0, WL1, . . . , WLm−1, and WLm. The word lines WL0, WL1, . . . , WLm−1, and WLm are connected to the word line voltage control sub-circuit 352 in the row voltage control circuit 350.

Each of the gates of the bit line select transistors 360a, . . . , 360n is connected to the bit line select control sub-circuit 351 within the row voltage control circuit 350 to provide the bit line select signals BLG0 and BLG1 for activation of the bit line select transistors 360a, . . . , 360n to connect a selected local bit lines LBL0, LBL1, . . . , LBLn−1, and LBLn to its associated global bit line GBL0, . . . , GBLn.

Each of the gates of the source line select transistors 365a, . . . , 365n is connected to the source line select control sub-circuit 353 within the row voltage control circuit 350 to provide the source line select signals SLG0 and SLG1 for activation of the source line select transistors 365a, . . . , 365n to connect a selected local source lines LSL0, LSL1, . . . , LSLn−1, and LSLn to its associated global source line GSL0, . . . , GSLn. Each of the gates of the bit line select transistors 360a, . . . , 360n is connected to the bit line select control circuit 351 within the row voltage control circuit 350 to connect the local bit lines LBL0, LBL1, . . . , LBLn−1, and LBLn to their associated global bit lines GBL0, . . . , GBLn.

The array 305 of dual charge retaining transistor NOR flash cells 310 includes at least one block (as shown) of the dual charge retaining transistor NOR flash cells 310 and may have multiple blocks. The block is further divided into two half blocks. The half blocks consist of alternating pages of the two charge retaining transistors M0 and M1. For each of the dual charge retaining transistor NOR flash cells 310 on each row, one of the two charge retaining transistors M0 or M1 is assigned to one page of the two charge retaining transistors M0 and M1. Thus one of the two charge retaining transistors M0 or M1 is assigned to one of the two half blocks and the other of the two charge retaining transistors M0 and M1 is assigned to the other half block. It should be noted that the charge retaining transistor NOR flash cells 310 may have more than the two charge retaining transistors M0 and M1. It is in keeping with the intent of this invention that the charge retaining transistor NOR flash cells 310 have at least two of the charge retaining transistors.

Each of the local bit lines LBL0, LBL1, . . . , LBLn−1, and LBLn are connected to their associated local source lines LSL0, LSL1, . . . , LSLn−1, and LSLn through the pass transistors 396a, 396b, . . . , 396n. The gates of the pass transistors 396a, 396b, . . . , 396n are connected to the program select signal 395 to bring the local bit line LBL0, LBL1, . . . , LBLn−1, and LBLn and the local source lines LSL0, LSL1, . . . , LSLn−1, and LSLn to an equal potential voltage level during a program operation to prevent punch through between the drains and sources of the two charge retaining transistors M0 and M1.

Refer now to FIG. 5 for a description of the row voltage control circuit 350. The row voltage control circuit 350 has a control decoder 405 that receives program timing and control signals 410, erase timing and control signals 415, and read timing and control signals 420. The control decoder 405 decodes the program timing and control signals 410, erase timing and control signals 415, and read timing and control signals 420 to establish the operation of the NOR flash nonvolatile memory device 300. The row voltage control circuit 350 has an address decoder 425 that receives and decodes an address signal 430 that provides the location of the selected charge retaining NOR flash cells 310 that are to be programmed, erased, or read.

The bit line select control sub-circuit 351 receives the decoded program, erase, and read timing and control signals from the control decoder 405 and the decoded addresses from the address decoder 425. The bit line select control sub-circuit 351 selects which of the bit line select signals BLG0 and BLG1 that activates the bit line select transistors 360a, . . . , 360n that connects the local bit line LBL0, LBL1, . . . , LBLn−1, and LBLn to which the selected NOR flash nonvolatile memory devices 300 are connected to the associated global bit lines GBL0, . . . , GBLn.

The source line select control sub-circuit 353 receives the decoded program, erase, and read timing and control signals from the control decoder 405 and the decoded addresses from the address decoder 425. The source line select control sub-circuit 353 selects which of the source line select signals SLG0 and SLG1 that activates the source line select transistors 365a, . . . , 365n that connects the local source lines LSL0, LSL1, . . . , LSLn−1, and LSLn to which the selected NOR flash nonvolatile memory device 300 is connected to the associated global source lines GSL0, . . . , GSLn.

The row voltage control circuit 350 includes the word line voltage control circuit 352 that has a program voltage generator 435, an erase voltage generator 440, a read voltage generator 445, and a row selector 450. The row selector 450 for transferring the program, erase, and read voltages from the program voltage generator 435, the erase voltage generator 440, and the read voltage generator 445 through the pass gate transistors Ml0, Ml1, . . . , Mlm−1, Mlm to the selected word lines WL0, WL1, WLm−1, and WLm. Further, during a program operation, the row selector 450 activates the program select line 395 to turn on the pass transistors 396a, 396b, 396n to bring the local bit line LBL0, LBL1, . . . , LBLn−1, and LBLn and the local source lines LSL0, LSL1, . . . , LSLn−1, and LSLn to an equal potential voltage level during a program operation to prevent punch through between the drains and sources of the two charge retaining transistors M0 and M1.

The program voltage generator 435 has a program voltage source 436 that is connected to the row selector 450 to provide a program voltage level V_{PGM}. The program voltage level V_{PGM} is applied to one of the selected word lines WL0, WL1, . . . , WLm−1, and WLm for setting the voltage threshold of the selected charge retaining transistor M0 or M1. A program inhibit voltage generator 437 provides a program inhibit voltage level V_{PGMI} to is transferred to the row selector 450 to be applied to the unselected word lines WL0, WL1, . . . , WLm−1, and WLm for inhibiting a disturb programming of the unselected pages of the block 305 of dual charge retaining transistor NOR flash cells 310.

The program select gating voltage generator 438 generates the program select gating voltage V_{PMGS} that is transferred to the bit line select control sub-circuit 351 and source line select control sub-circuit 353 for connecting global bit lines GBL0, . . . , GBLn to the local bit line LBL0, LBL1, . . . , LBLn−1, and LBLn and the global source lines GSL0, . . . , GSLn and the local source lines LSL0, LSL1, . . . , LSLn−1, and LSLn for providing the programming voltage level to drain/sources and the source/drains of the selected charge retaining transistors M0 and M1. The program unselect gating voltage generator 439 generates the program unselect gating voltage V_{PMGU} that is transferred to the bit line select control sub-circuit 351 and source line select control sub-circuit 353 for connecting global bit lines GBL0, . . . , GBLn to the local bit line LBL0, LBL1, . . . , LBLn−1, and LBLn and the global source lines GSL0, . . . , GSLn and the local source lines LSL0, LSL1, . . . , LSLn−1, and LSLn for block the programming voltage level to drain/sources and the source/drains of the unselected charge retaining transistors M0 and M1.

The erase voltage generator 440 has a erase voltage generator 441 that is connected to the row selector 450 to provide the erase voltage level V_{ERS} to the word lines WL0, WL1, . . . , WLm−1, and WLm of the selected pages of the NOR flash nonvolatile memory device 300 to erase selected charge retaining transistors M0 and M1. The erase voltage generator 440 also has a erase inhibit voltage generator 442 that is connected to the row selector 450 to provide the necessary erase inhibit voltage level V_{ERSI} to the word lines WL0, WL1, . . . , WLm−1, and WLm of the unselected pages of the NOR flash nonvolatile memory device 300 to prevent erasing of the unselected charge retaining transistors M0 and M1. The erase voltage generator 440 includes an erase select gating voltage generator 443 to provide the erase select gate voltage level V_{ERSGS} to the bit line select control sub-circuit 351 and source line select control sub-circuit 353 for providing the erase select gate voltage level V_{ERSGS} to connect global bit lines GBL0, . . . , GBLn to the local bit line LBL0, LBL1, . . . , LBLn−1, and LBLn and the global source lines GSL0, . . . , GSLn and the local source lines LSL0, LSL1, . . . , LSLn−1, and LSLn. The erase voltage generator 440 includes an erase unselect gating voltage generator 444 to provide the erase unselect gate voltage level V_{ERSGU} to the bit line select control sub-circuit 351 and source line select control sub-circuit 353 for providing the erase unselect gate voltage level V_{ERSGU} to disconnect global bit lines GBL0, . . . , GBLn from the local bit line LBL0, LBL1, . . . , LBLn−1, and LBLn and the global source lines GSL0, . . . , GSLn and the local source lines LSL0, LSL1, . . . , LSLn−1, and LSLn.

The read voltage generator 445 has a read/verify voltage generator 446 to provide the necessary read reference voltage V_{R} and a verify threshold voltage levels Vtnx to the control gates of the selected word line of the charge retaining transistors M0 and M1 for reading single level and multiple level cell data. The read voltage generator 445 has read pass voltage generator 447 to provide the read pass voltage level V_{RPASS} to the control gate of the unselected charge retaining transistors M0 and M1 of the selected dual charge retaining transistor NOR flash cells 310. The read voltage generator 445 has read inhibit voltage generator 451 to provide the read inhibit voltage level V_{RI} to the control gate of the charge retaining transistors M0 and M1 of the unselected dual charge retaining transistor NOR flash cells 310.

The read voltage generator 445 has a read select voltage generator 448 to provide a read select gate voltage level V_{RGS} to the gates of the bit line select transistors 360a, . . . , 360n and source line select transistors 365a, . . . , 365n for connecting the global bit lines GBL0, . . . , GBLn to the local bit line LBL0, LBL1, . . . , LBLn−1, and LBLn and the global source lines GSL0, . . . , GSLn to the local source lines LSL0, LSL1, . . . , LSLn−1, and LSLn in a read or verify operation. The read voltage generator 445 has a read unselect voltage generator 448 to provide a read unselect gate voltage level V_{RGU} to the gates of the bit line select transistors 360a, . . . , 360n and source line select transistors 365a, . . . , 365n for disconnecting the global bit lines GBL0, . . . , GBLn from the local bit line LBL0, LBL1, . . . , LBLn−1, and LBLn and is the global source lines GSL0, . . . , GSLn from the local source lines LSL0, LSL1, . . . , LSLn−1, and LSLn in a read or verify operation.

Refer now to FIG. 6 for a description of the column voltage control circuit 355. The column voltage control circuit 355 has a control decoder 505 that receives program timing and control signals 510, erase timing and control signals 515, and read timing and control signals 520. The control decoder 505 decodes the program timing and control signals 510, erase timing and control signals 515, and read timing and control signals 520 to establish the operation of the NOR flash nonvolatile memory device 300. The column voltage control circuit 355 has an address decoder 525 that receives and decodes an address signal 530 that provides the locations of the selected charge retaining cell 310 that are to be programmed, erased, or read.

The column voltage control circuit 355 includes a program voltage generator 535, a read voltage generator 545, and a column selector 550. The program voltage generator 535 has a program voltage source 536 that provides a drain/source program voltage level V_{D/S}_{_{—}}_{P} to the drains and sources of the selected charge retaining transistors M0 and M1 for programming of the selected charge retaining transistors M0 and M1. A ground reference voltage level 537 is provided to drain and source of the selected charge retaining transistors M0 and M1 during the program operation to establish the voltage field between the charge retaining and the sources and drains of the unselected charge retaining transistors M0 and M1 for inhibiting programming the selected charge retaining transistors M0 and M1.

During the erase operation of this invention, the sources and drains of the charge retaining transistors M0 and M1 are coupled to a drain/source erase voltage level V_{TW} from the diffusion well (TPW, N-WELL, TNW). The global bit lines GBL0, . . . , GBLn and the global source lines GSL0, . . . , GSLn are disconnected within the column selector 550 and allowed to float.

The read voltage generator 545 has a read bias voltage source 546 to provide the necessary read bias voltage V_{RDB} to the global bit lines GBL0, . . . , GBLn and thus to the drain/source of the selected of the charge retaining transistors M0 and is M1 for reading the data state of the selected charge retaining transistors M0 and M1. The read voltage generator also provides the ground reference voltage level 547 to the global source lines GSL0, . . . , GSLn and thus to the source/drains of the selected charge retaining transistors M0 and M1. In the read operation, the global bit lines GBL0, . . . , GBLn are connected to the sense amplifier 555 by the column selector 555 to determine the data state of the selected charge retaining transistors M0 and M1.

The column selector 550 provides the select switching signals for transferring the program, erase (floating), and read voltages from the program voltage generator 535 and the read voltage generator 545 to the selected global bit lines GBL0, . . . , GBLn and selected global source lines GSL0, . . . , GSLn.

The column voltage control circuit 355 has a well bias control circuit 565 that includes a diffusion well voltage generator 567, a deep well voltage generator 568 and a substrate biasing voltage generator 569. The diffusion well voltage generator 567 is connected to the shallow P-type diffusion well TPW of FIG. 2b-2 or 2c-2, or the N-type well N-Well of FIG. 3b-2 or 3c-2, or the shallow N-type diffusion well TNW of FIGS. 2d-2 or 2e-2. The deep well generator 568 is connected to a deep diffusion well DNW of FIG. 2b-2 or 2c-2, or DPW of FIG. 3d-2 or 3e-2 or to the substrate of FIG. 3b-2 or 3e-2. The substrate biasing voltage generator 569 is connected to the substrate to provide a substrate biasing voltage level V_{SUB}. The substrate biasing voltage level V_{SUB} is the ground reference voltage level or the voltage level of the power supply voltage source to the substrate dependent upon the impurity type of the substrate. In embodiments where the substrate is an N-type impurity, the substrate biasing voltage level V_{SUB} is the ground reference voltage level. In embodiments where the substrate is a P-type impurity, the substrate biasing voltage level V_{SUB} is the voltage level of the to power supply voltage source VDD.

The deep well voltage generator 568 generates a deep well biasing voltage level V_{DW} for those embodiments including a triple well structure as in FIGS. 2b-2, 2c-2, 3d-2, and 3e-2. For programming, verification, and reading of the array 300 of NOR flash memory cells 310, the deep well biasing voltage level V_{DW} is the voltage level of the power supply voltage source for the embodiments where the deep well is doped with an N-type impurity. Also, for programming, verification, and reading of the array 300 of NOR flash memory cells 310, the deep well biasing voltage level V_{ow} is the ground reference voltage level for the embodiments where the deep well is doped with an P-type impurity. For erasing a selected block 305 or page 315 of the array 300 of NOR flash memory cells 310, the deep well biasing voltage level V_{DW} is a well erase biasing voltage level.

The shallow well voltage generator 567 transfers a diffusion well voltage level V_{TW} to the triple wells TPW and TNW as in FIGS. 2b-2, 2c-2, 3d-2, and 3e-2 or the diffusion well N-WELL of FIGS. 3b-2 and 3c-2. The shallow well voltage generator 567 generates the erase voltage level that is applied to the triple wells TPW and TNW and the diffusion well N-WELL to attract the charges from the charge retaining of the selected charge retaining transistors M0 or M1. The erase voltage level that is generated by the deep well generator 568 and the shallow well generator 567 prevent undesired forward currents between the deep wells DNW and DPW and the triple diffusion well TPW and TNW. Similarly, the shallow well voltage generator 567 generates the program voltage level that is applied to the triple wells TPW and TNW and the diffusion well N-WELL to attract the charges to the charge retaining of the selected charge retaining transistors M0 or M1.

FIGS. 7-16 are tables illustrating the voltage conditions for operating an array of dual charge retaining transistor NOR flash memory cells for reading, erasing, erase verifying, programming, and program verifying selected dual charge retaining NOR flash memory cells embodying the principles of the present invention. In all embodiments of the nonvolatile memory device having an array of dual charge retaining transistor NOR flash memory cells, the voltage level of the power supply voltage source is equal to 1.7V˜1.9V or 2.7V˜3.6V.

FIG. 7 illustrates the reading, erasing, erase verifying, programming, and program verifying biasing voltages for the array of dual charge retaining transistor NOR flash memory cells that are structured to be N-channel floating gate transistors formed in a triple P-well. The program state has a threshold voltage level of the second is threshold voltage level Vt1 and the erase state has a threshold voltage level of the first threshold voltage level Vt0.

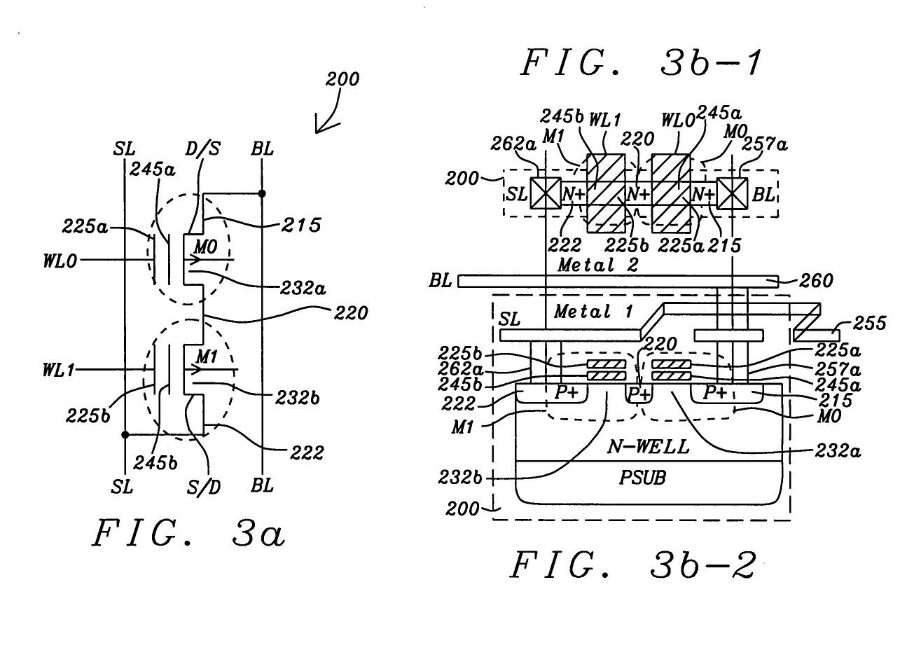

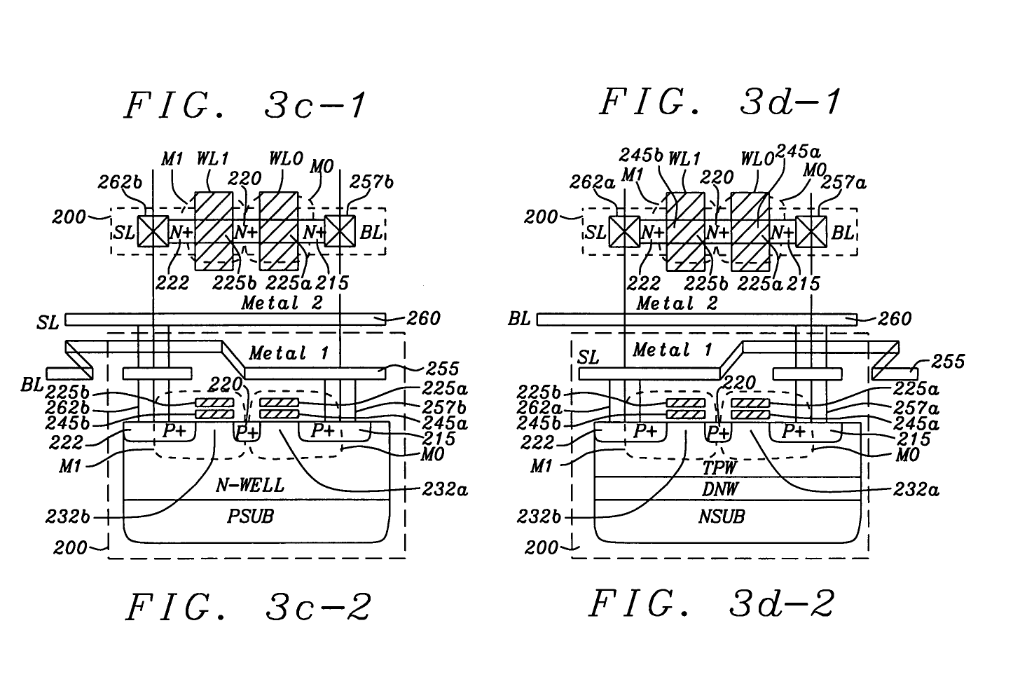

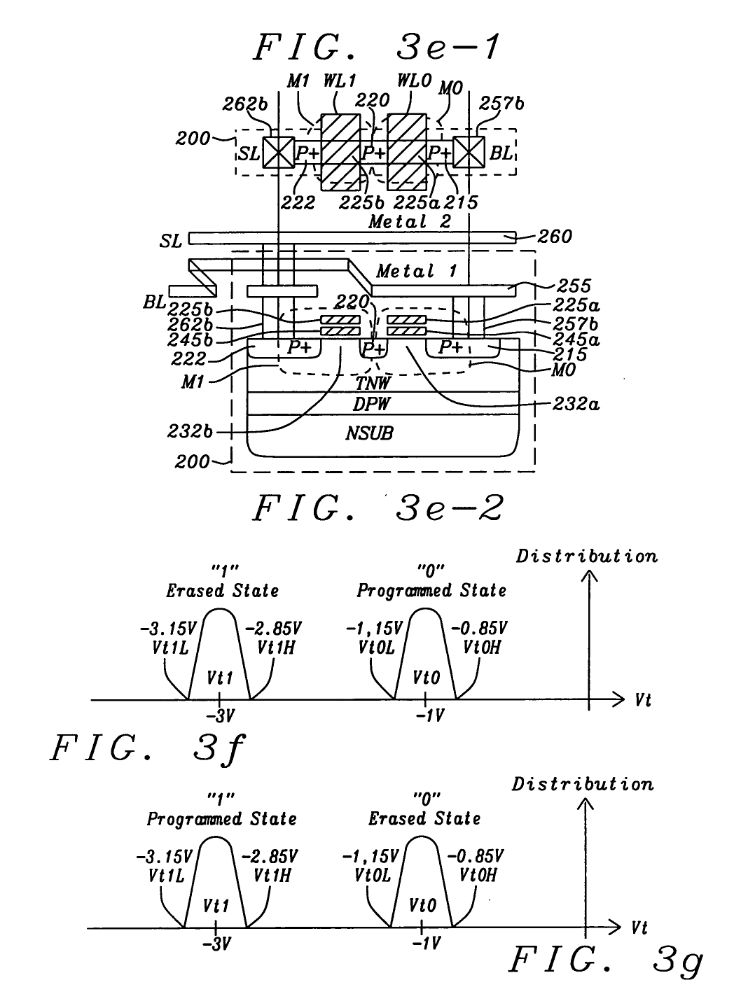

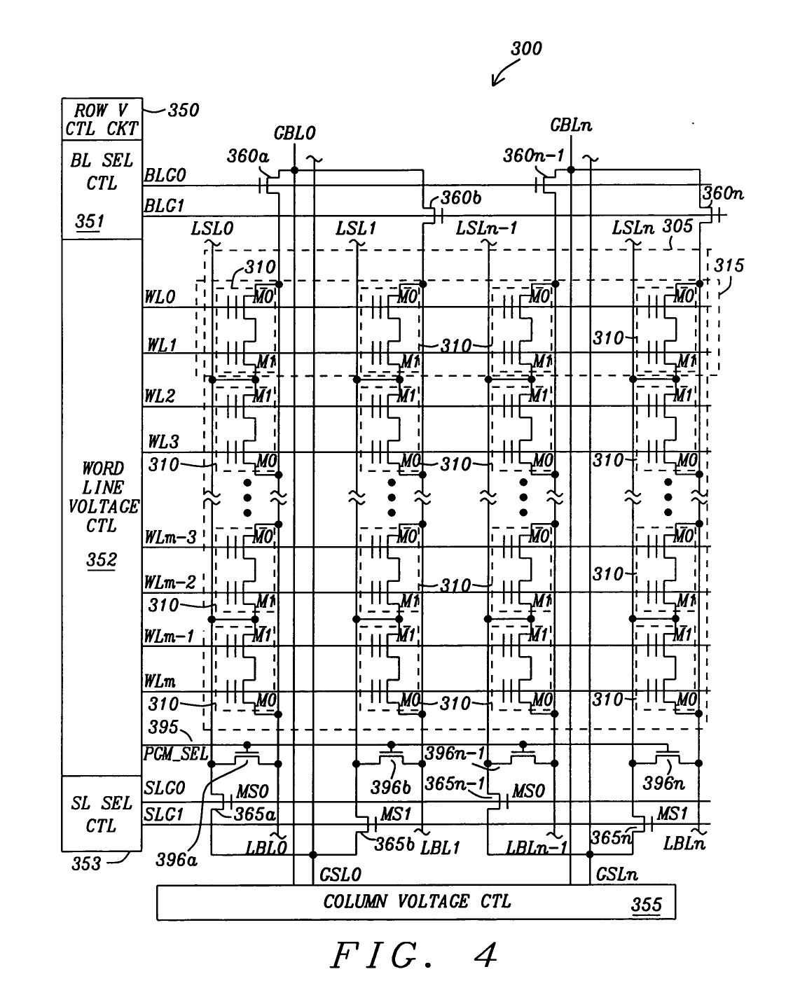

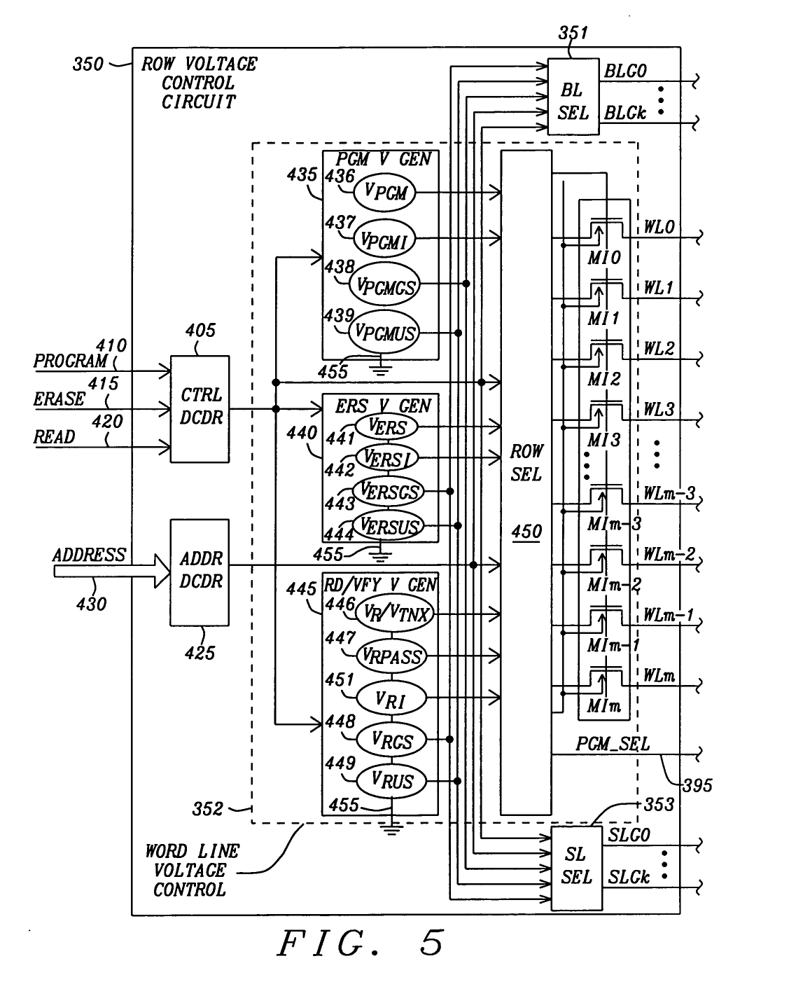

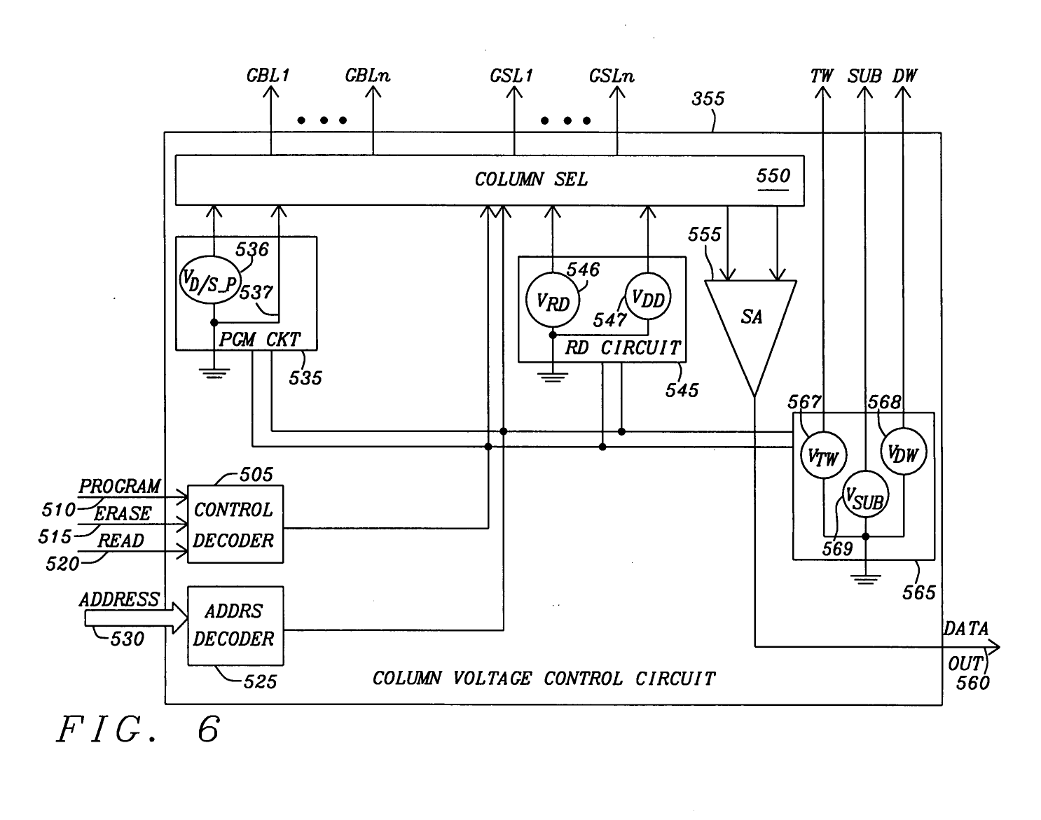

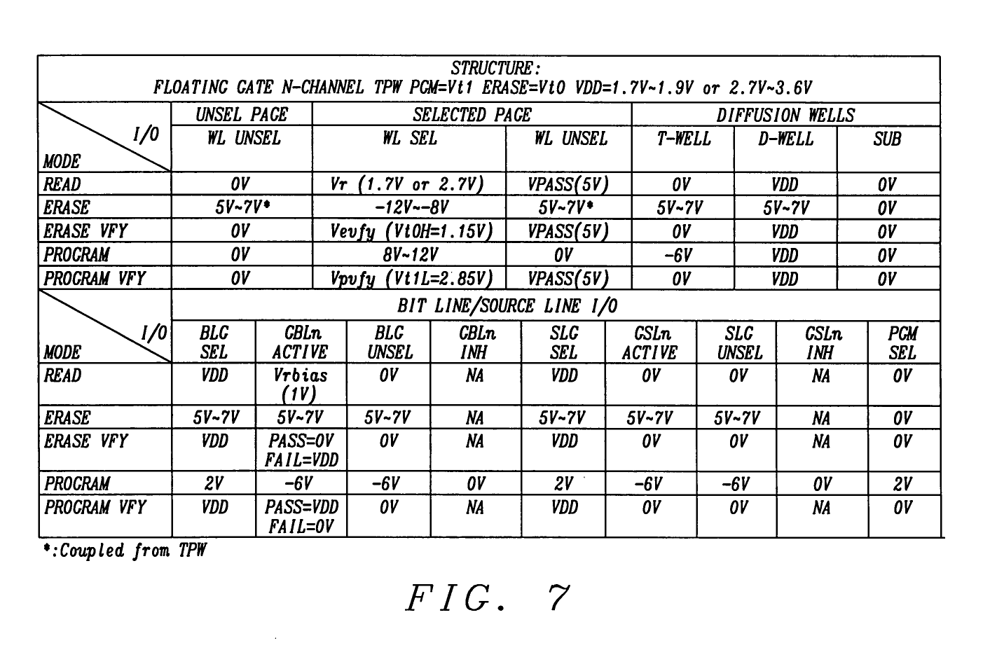

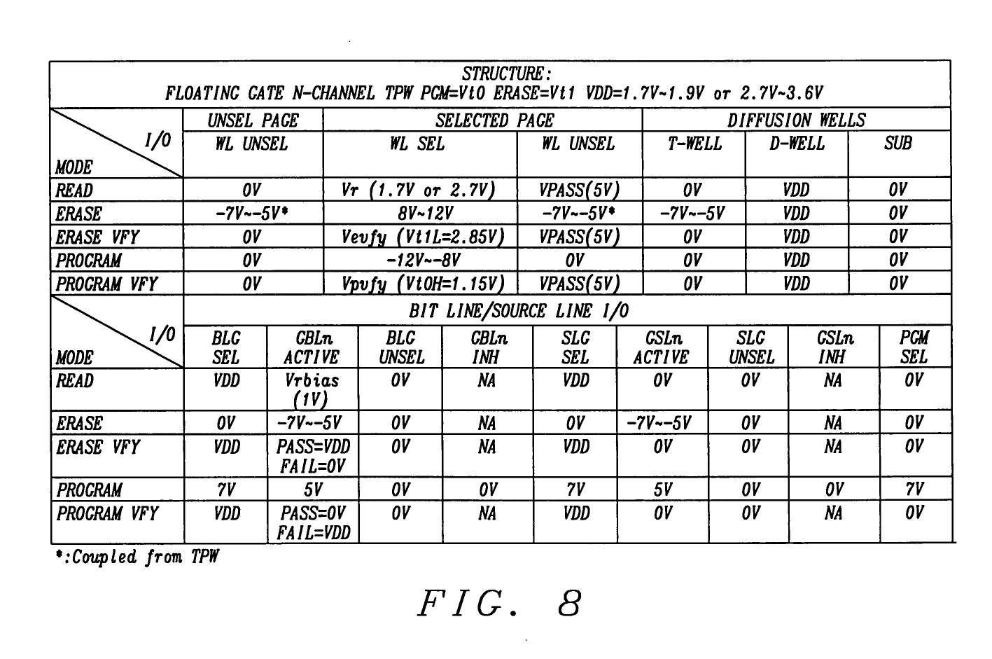

FIG. 8 illustrates the reading, erasing, erase verifying, programming, and program verifying biasing voltages for the array of dual charge retaining transistor NOR flash memory cells that are structured to be N-channel floating gate transistors formed in a triple P-well. The program state has a threshold voltage level of the first threshold voltage level Vt0 and the erase state has a threshold voltage level of the second threshold voltage level Vt1.

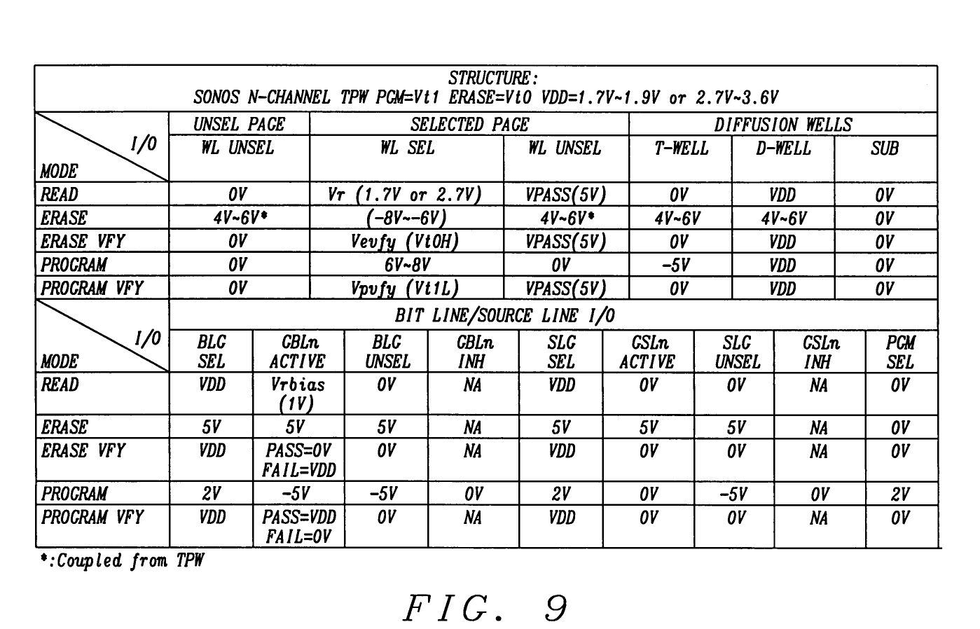

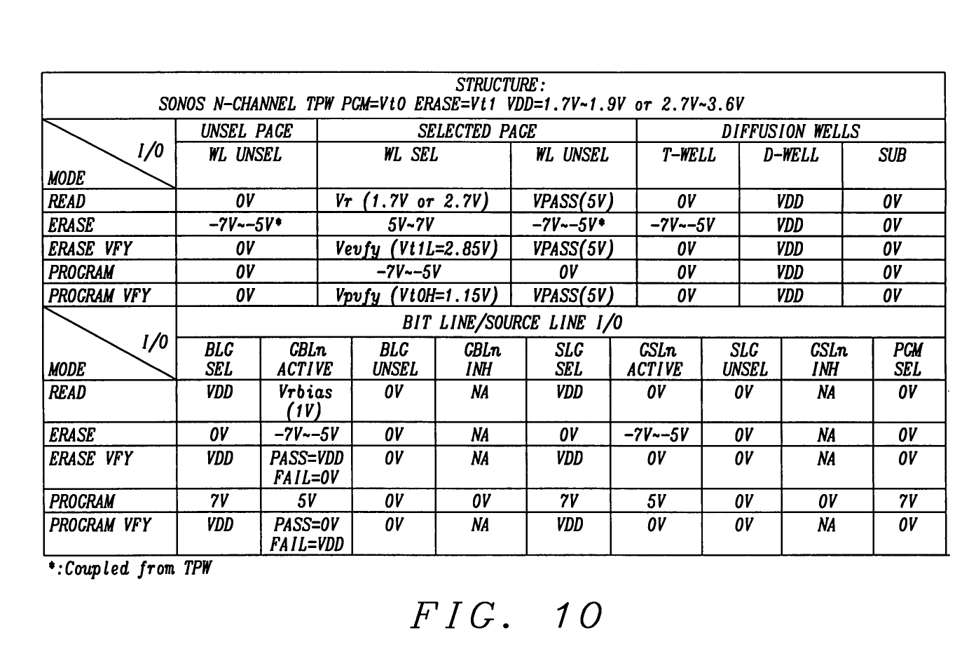

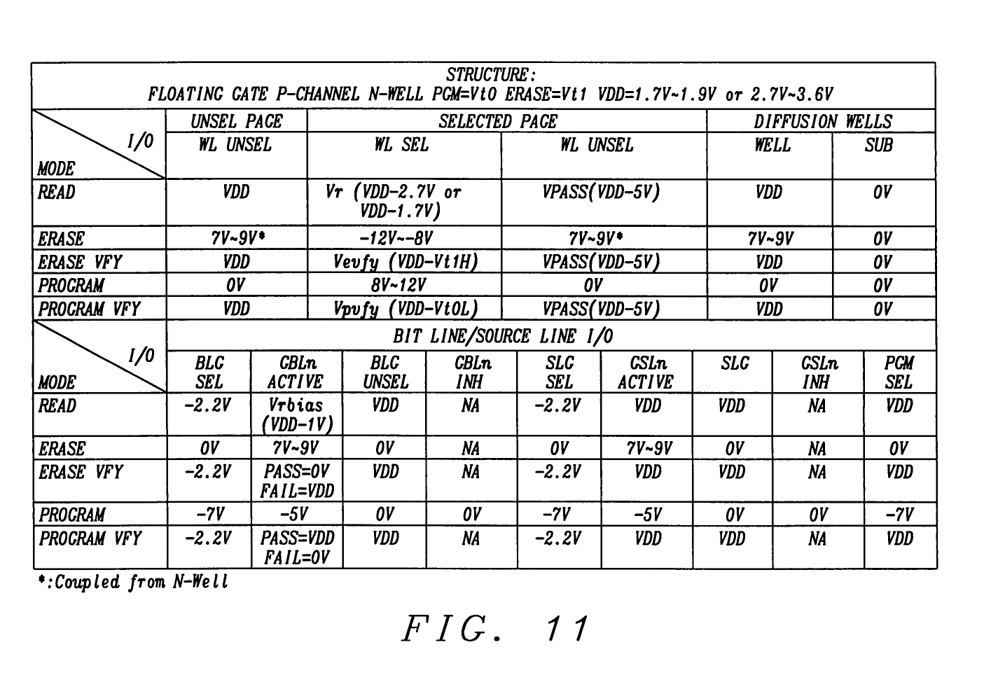

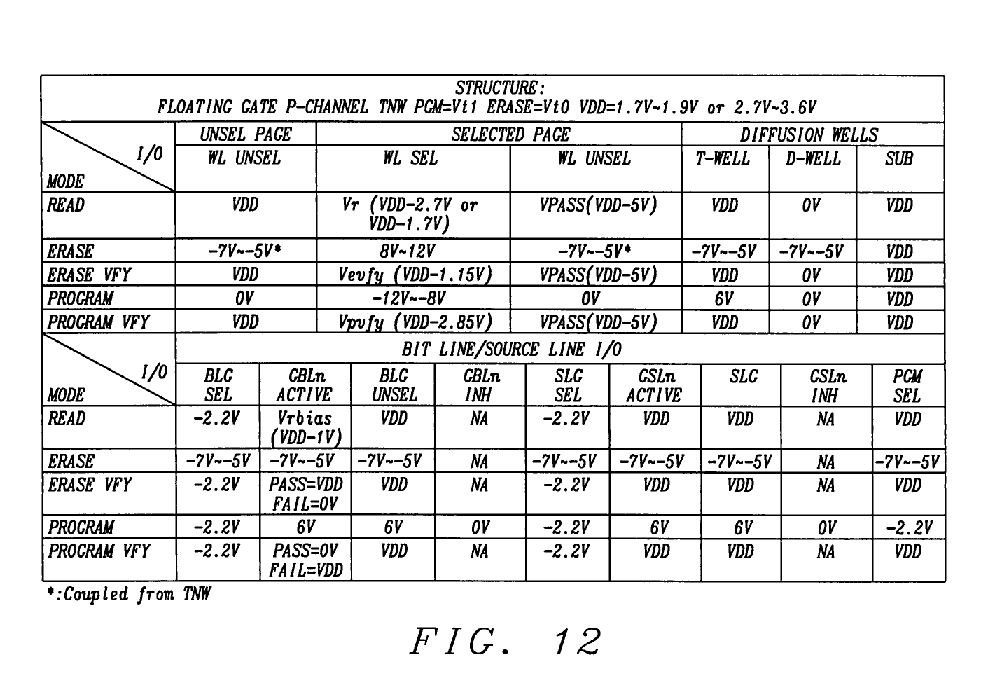

FIG. 9 illustrates the reading, erasing, erase verifying, programming, and program verifying biasing voltages for the array of dual charge retaining transistor NOR flash memory cells that are structured to be N-channel SONOS charge trapping transistors formed in a triple P-well. The program state has a threshold voltage level of the second threshold voltage level Vt1 and the erase state has a threshold voltage level of the first threshold voltage level Vt0.

FIG. 10 illustrates the reading, erasing, erase verifying, programming, and program verifying biasing voltages for the array of dual charge retaining transistor NOR flash memory cells that are structured to be N-channel SONOS charge trapping transistors formed in a triple P-well. The program state has a threshold voltage level of the first threshold voltage level Vt0 and the erase state has a threshold voltage level of the second threshold voltage level Vt1.

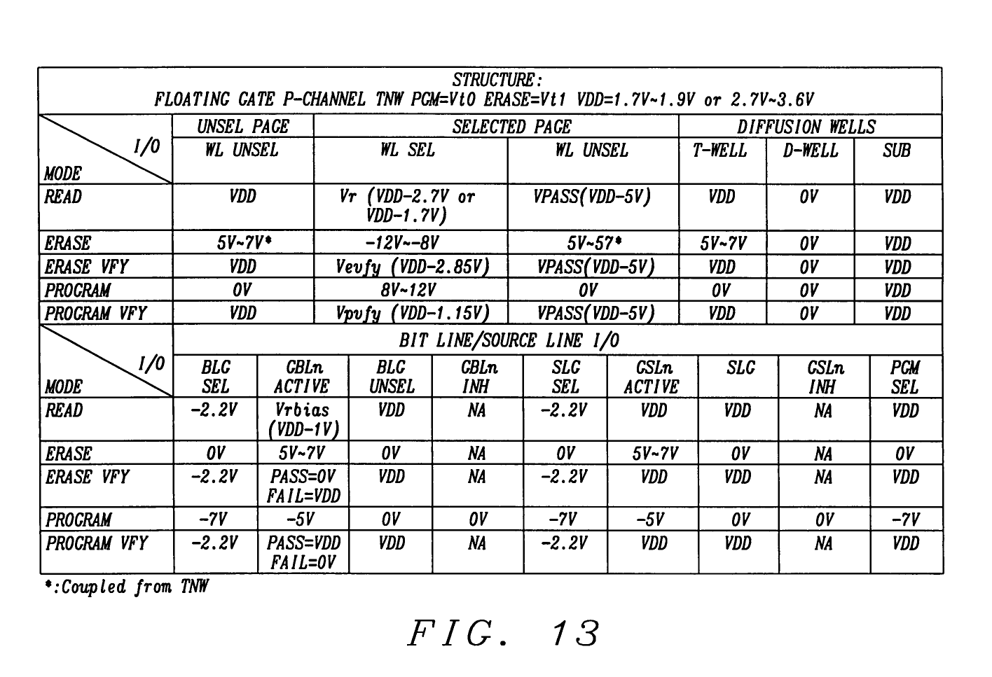

FIG. 11 illustrates the reading, erasing, erase verifying, programming, and program verifying biasing voltages for the array of dual charge retaining transistor NOR flash memory cells that are structured to be P-channel floating gate transistors formed in a N-type diffusion single well structure. The program state has a threshold voltage level of the first threshold voltage level Vt0 and the erase state has a threshold voltage level of the second threshold voltage level Vt1.

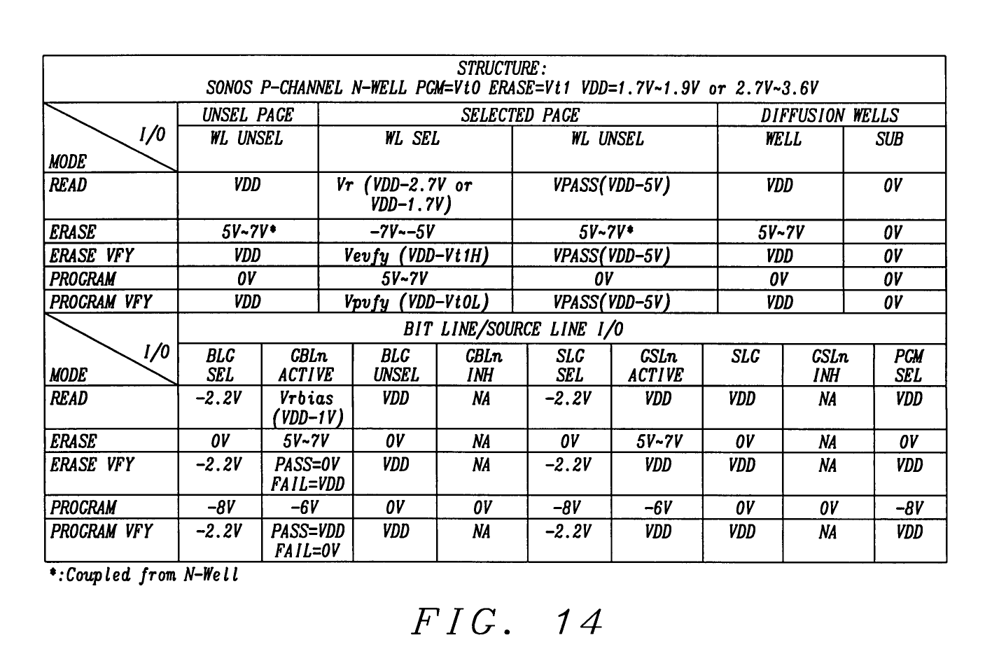

FIG. 12 illustrates the reading, erasing, erase verifying, programming, and program verifying biasing voltages for the array of dual charge retaining transistor NOR is flash memory cells that are structured to be P-channel floating gate transistors formed in a triple N-well. The program state has a threshold voltage level of the second threshold voltage level Vt1 and the erase state has a threshold voltage level of the first threshold voltage level Vt0.

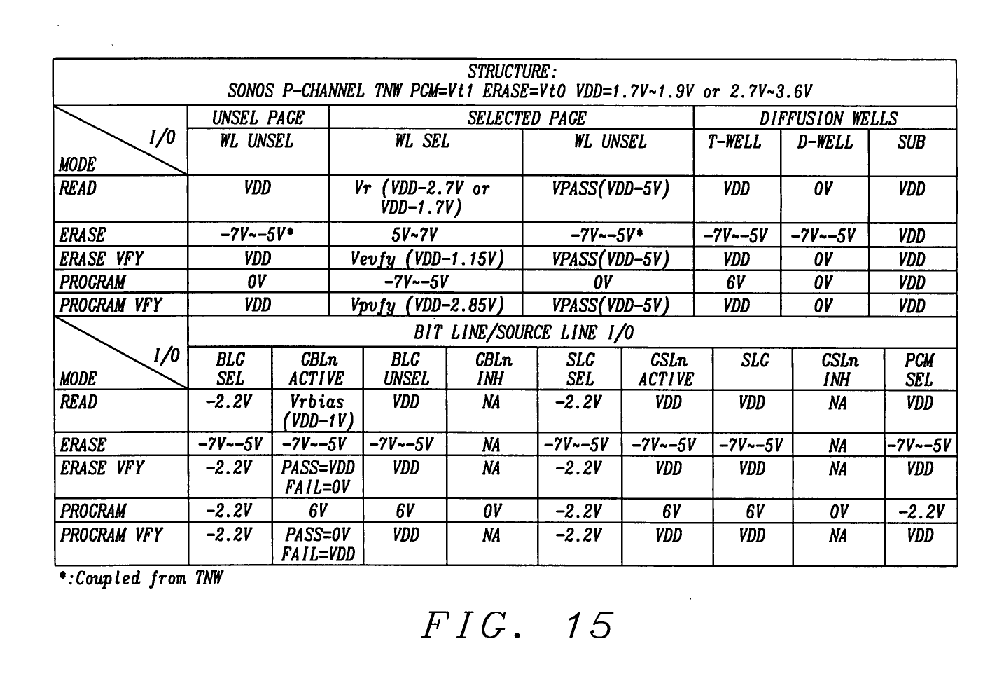

FIG. 13 illustrates the reading, erasing, erase verifying, programming, and program verifying biasing voltages for the array of dual charge retaining transistor NOR flash memory cells that are structured to be P-channel floating gate transistors formed in a triple N-well. The program state has a threshold voltage level of the first threshold voltage level Vt0 and the erase state has a threshold voltage level of the second threshold voltage level Vt1.

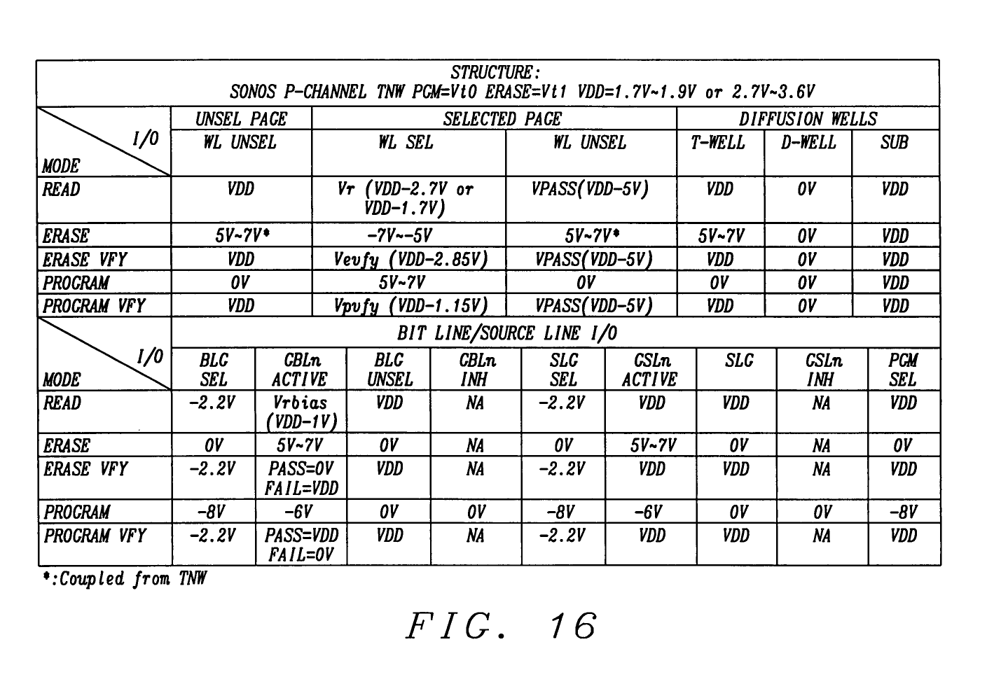

FIG. 14 illustrates the reading, erasing, erase verifying, programming, and program verifying biasing voltages for the array of dual charge retaining transistor NOR flash memory cells that are structured to be P-channel SONOS charge trapping transistors formed in a N-type diffusion single well structure. The program state has a threshold voltage level of the first threshold voltage level Vt0 and the erase state has a threshold voltage level of the second threshold voltage level Vt1.

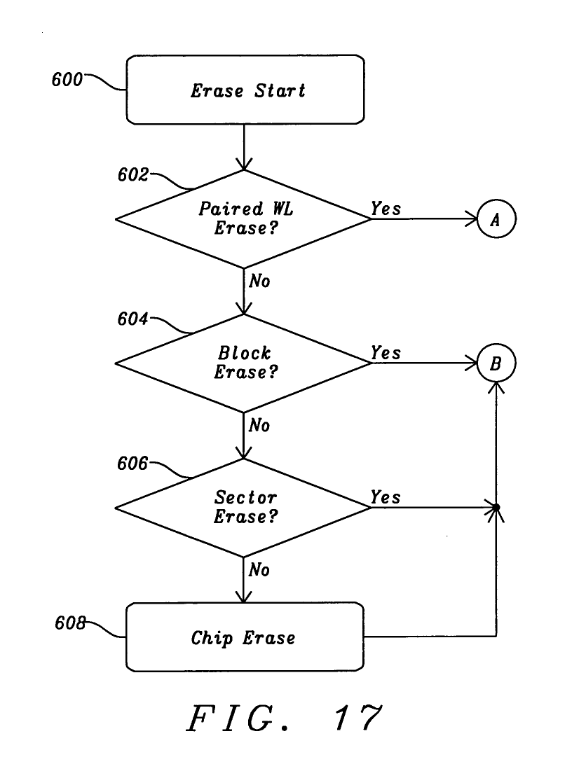

FIG. 15 illustrates the reading, erasing, erase verifying, programming, and program verifying biasing voltages for the array of dual charge retaining transistor NOR flash memory cells that are structured to be P-channel SONOS charge trapping transistors formed in a triple N-well. The program state has a threshold voltage level of the second threshold voltage level Vt1 and the erase state has a threshold voltage level of the first threshold voltage level Vt0.

FIG. 16 illustrates the reading, erasing, erase verifying, programming, and program verifying biasing voltages for the array of dual charge retaining transistor NOR flash memory cells that are structured to be P-channel SONOS charge trapping transistors formed in a triple N-well. The program state has a threshold voltage level of the first threshold voltage level Vt0 and the erase state has a threshold voltage level of the second threshold voltage level Vt1.

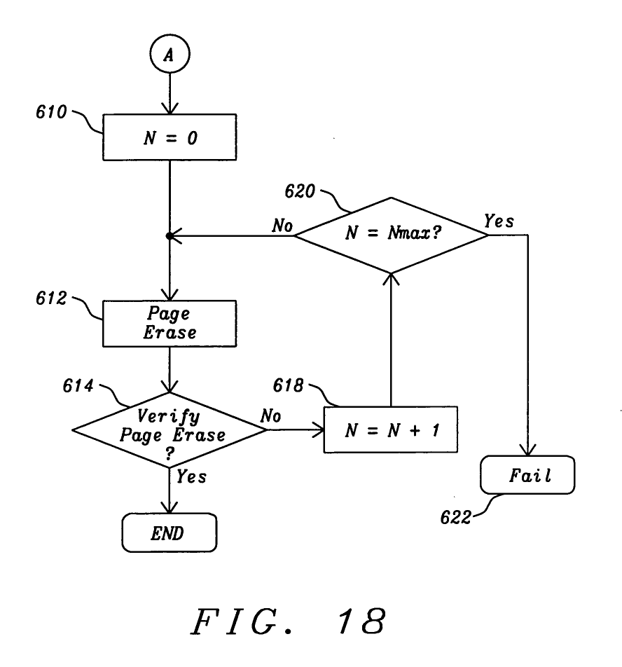

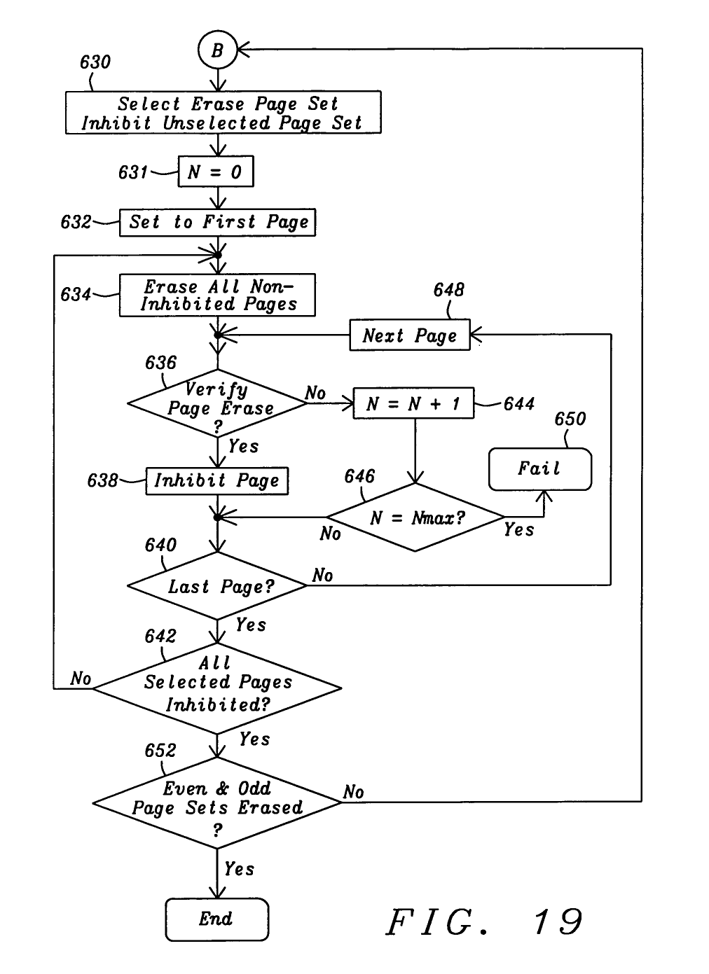

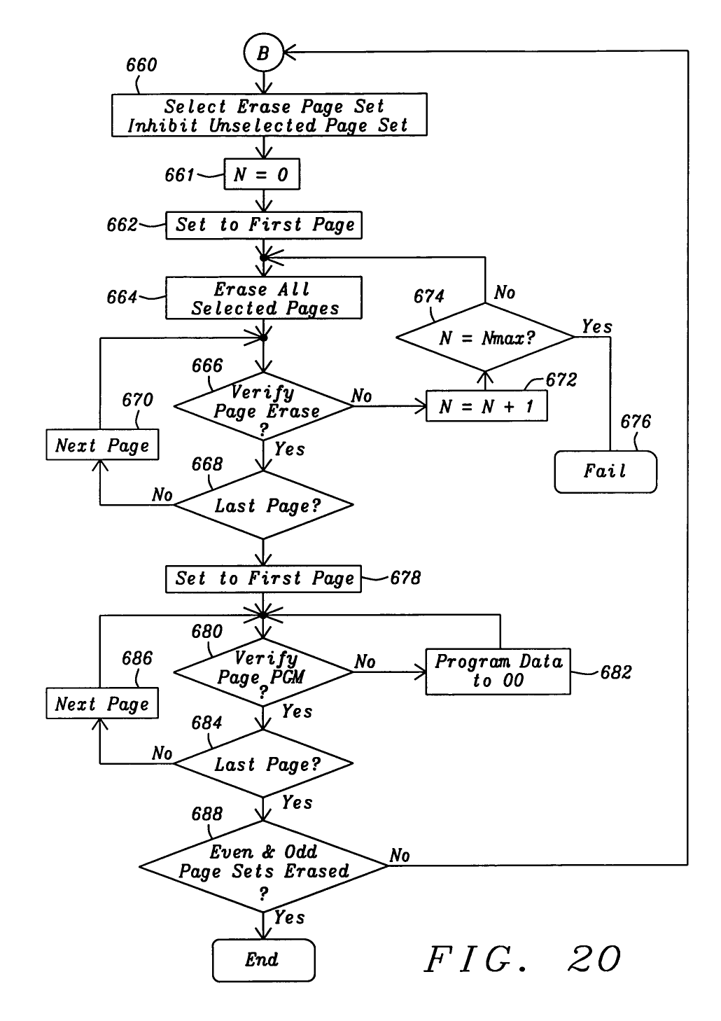

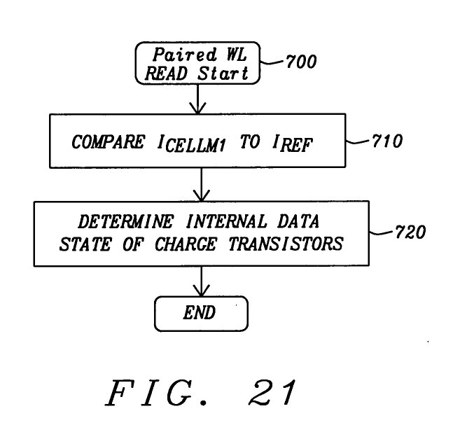

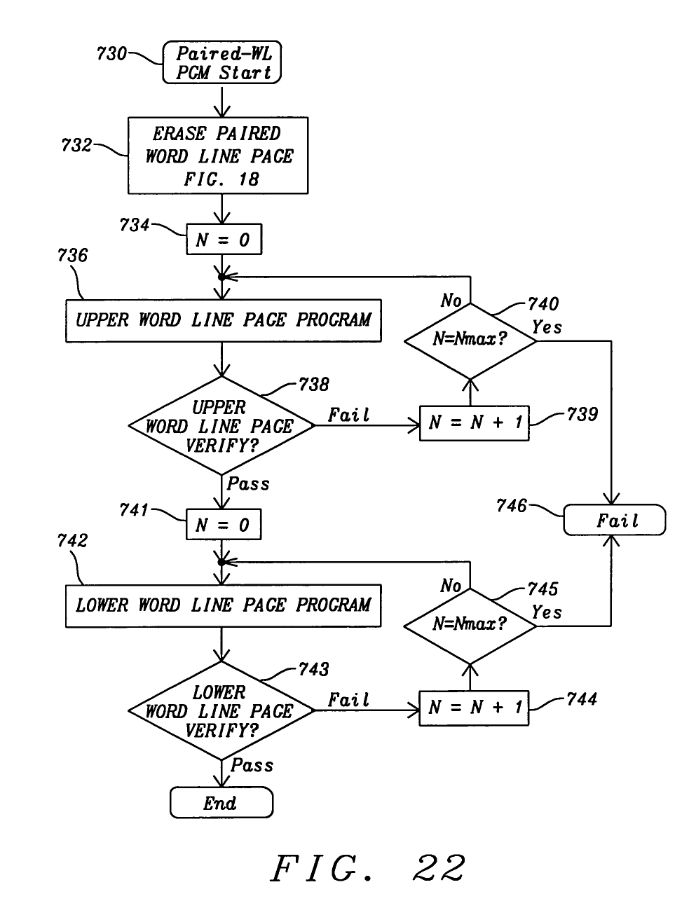

FIG. 17 is a flow chart of an erase operation for an array of dual charge retaining transistor NOR flash memory cells. FIG. 18 is a flow chart of an erase operation for a paired word line page of dual charge retaining transistor NOR flash memory cells within an array of dual charge retaining transistor NOR flash memory cells. FIG. 19 is a flow chart of an erase operation for a block, sector, or an entire chip of an array of dual charge retaining transistor NOR flash memory cells. FIG. 20 is a flow chart of an erase operation with reprogramming for a block, sector, or an entire chip of an array of dual charge retaining transistor NOR flash memory cells. FIG. 21 is a flow chart of a read operation for dual charge retaining transistor NOR flash memory cells of an array of dual charge retaining transistor NOR flash memory cells. FIG. 22 is a flow chart of a program operation for of a paired word line page of dual charge retaining transistor NOR flash memory cells of an array of dual charge retaining transistor NOR flash memory cells.

For a discussion of the erase operation of selected dual charge retaining transistor NOR flash memory cells 310, refer now to FIGS. 4-6 and 17. For this discussion, the selected paired word line pages 315 of the dual charge retaining transistor NOR flash memory cells 310 are connected to the word lines WL0 and WL1 and the unselected paired word line pages or the dual charge retaining transistor NOR flash memory cells 310 are connected to the word lines WL2, WL3, . . . , WLm−1, and WLm. The page of the charge retaining transistors M0 connected to the word line WL0 are the selected page. In FIG. 17 an input command is decoded to determine if it is an erase operation. If the command is for an erase operation the procedure begins (Box 600) by determining if the erase operation is an erasure of a single paired word line page 315 of dual charge retaining transistor NOR flash memory cells 310 (Box 602); determining if the erase operation is the erasure of a block of the dual charge retaining transistor NOR flash memory cells 310 (Box 604); determining if the erase operation is the erasure of a sector of the dual charge retaining transistor NOR flash memory cells 310 (Box 606); and determining if the erase operation is the erasure of an entire chip of the dual charge retaining transistor NOR flash memory cells 310 (Box 608).

If the erase operation is determined (Box 602) to be erasure of a single paired word line page 315 of dual charge retaining transistor NOR flash memory cells 310, an erase counter is initialized (Box 610). The single paired word line page 315 of dual charge retaining transistor NOR flash memory cells 310 is erased (Box 612). Refer now to FIGS. 7-16 for voltage levels applied to the array of the dual charge retaining transistor NOR flash memory cells 310 to erase a single paired word line pages of the dual charge retaining transistor NOR flash memory cells 310. The voltage levels are determined according whether the dual charge retaining transistor NOR flash memory cells 310 are floating gate or SONOS charge trapping flash nonvolatile transistors and are N-channel or P-channel flash nonvolatile transistors. Further, the erase threshold voltage level to which the dual charge retaining transistor NOR flash memory cells 310 are to be erase determine the erase biasing voltage levels. The unselected dual charge retaining transistor NOR flash memory cells 310 are similarly biased according the voltage levels of FIGS. 7-16 to inhibit any disturbances during the erasing operation.

The single paired word line page 315 of dual charge retaining transistor NOR flash memory cells 310 are then verified (Box 614). Refer back to FIGS. 7-16 for the biasing voltage levels of the dual charge retaining transistor NOR flash memory cells 310 to be verified. The read bias voltage level V_{RDB} is applied as the power supply voltage source VDD to the selected global source lines GSL0, . . . , GSLn and the ground reference voltage level is applied to the global bit lines GBL0, . . . , GBLn. The sense amplifier detects the voltage level of the global bit lines GBL0, . . . , GBLn and thus the selected local bit lines. Dependent upon the erased threshold voltage level and the structure of the selected charge retaining transistors M0, the selected charge retaining transistor M0 are considered to have passed if the detected voltage is either the voltage level of the power supply voltage source VDD or the ground reference voltage level. FIGS. 7-16 show the pass and fail criteria for each of the structures and thresholds.

If any of the selected charge retaining transistors M0 and M1 have not been sufficiently erased such that their threshold voltage level has achieved the erased threshold voltage level, they have failed the verification (Box 614) of the paired word line page 315 of dual charge retaining transistor NOR flash memory cells 310, the erase is counter is incremented (Box 616) and the erase counter is compared (Box 618) to the maximum erase count Nmax. If the erase counter exceeds the maximum erase count Nmax, the nonvolatile memory device 300 has failed (Box 620). If the erase counter does not exceed the maximum erase count Nmax, the paired word line page of dual charge retaining transistor NOR flash memory cells is erased (Box 612) and erase verified (Box 614) until all of the charge retaining transistors M0 and M1 of the paired word line page of dual charge retaining transistor NOR flash memory cells 310 pass. If the charge retaining transistors M0 are successfully programmed, the page erase operation is complete.

Referring back to FIG. 17, if the erase is determined to be a block erase (Box 604), sector erase (Box 606), or chip erase (Box 608), the erase procedure is as described in FIG. 19 for an erase without any reprogramming and FIG. 20 for an erase with reprogramming. Referring to FIG. 19, the erase is structured to erase in half block, half sector, or half chip increments. The page set to be erased for the half block, half sector, or half chip is chosen (Box 630) and the pages of the unselected page set are inhibited. An erase counter N is initialized (Box 631) to contain an erase count and the first page to be erased is selected (Box 632). The selected non-inhibited pages are collectively erased (Box 634). Refer now to FIGS. 7-16 for voltage levels applied to the array of the dual charge retaining transistor NOR flash memory cells 310 to erase (Box 634) the selected word line pages of the dual charge retaining transistor NOR flash memory cells 310. The voltage levels are determined according whether the dual charge retaining transistor NOR flash memory cells 310 are floating gate or SONOS charge trapping flash nonvolatile transistors and are N-channel or P-channel flash nonvolatile transistors. Further, the erase threshold voltage level to which the dual charge retaining transistor NOR flash memory cells 310 are to be erase determine the erase biasing voltage levels. The unselected dual charge retaining transistor NOR flash memory cells 310 are similarly biased according the voltage levels of FIGS. 7-16 to inhibit any disturbances during the erasing operation.

The first page 315 of the selected word line pages of dual charge retaining transistor NOR flash memory cells 310 is then page verified (Box 636). Refer back to FIGS. 7-16 for the biasing voltage levels of the dual charge retaining transistor NOR flash memory cells 310 to be verified. The read bias voltage level V_{RDB} is applied as the power supply voltage source VDD to the selected global source lines GSL0, . . . , GSLn and the ground reference voltage level is applied to the global bit lines GBL0, . . . , GBLn. The sense amplifier detects the voltage level of global bit lines GBL0, . . . , GBLn and thus the selected local bit lines. Dependent upon the erased threshold voltage level and the structure of the selected charge retaining transistors M0, the selected charge retaining transistor M0 are considered to have passed if the detected voltage is either the voltage level of the power supply voltage source VDD or the ground reference voltage level. FIGS. 7-16 show the pass and fail criteria for each of the structures and threshold.

If any of the selected pages of the charge retaining transistors M0 and M1 have not been sufficiently erased such that their threshold voltage level is the erased threshold voltage level, the selected pages of the charge retaining transistors M0 and M1 have failed the verification (Box 636). The erase counter is incremented (Box 644) and the erase counter is compared (Box 646) to the maximum erase count Nmax. If the erase counter exceeds the maximum erase count Nmax, the nonvolatile memory device 300 has failed (Box 650). If the erase counter does not exceed the maximum erase count Nmax, the page counter is examined (Box 640) to determine if the last page of the selected set of pages of the charge retaining transistors M0 and M1 have been verified. If the last page has not been verified (Box 636), the next page is selected (Box 648) and the page verified (Box 636). If the page has been successfully erased, the page is inhibited (Box 638) and the page counter is examined (Box 640) to determine if the last page of the selected set of pages of the charge retaining transistors M0 and M1 have been verified. Each page is verified (Box 636) and if not successfully erased, the erase count is incremented (Box 644). If the verified page is completely erased, the page is inhibited (Box 638). When all the pages are verified (Box 636), the pages are examined (Box 642) to determine if all the pages are inhibited. If they are not all inhibited, the non-inhibited pages are collectively erased (Box 634) and verified (Box 636). The iterative process continues until all the pages are shown to be inhibited when is examined (Box 642). The array is examined (Box 652) to determine if both even and odd page sets of the half block, half sector, or half chip of the array of the dual charge retaining transistor NOR flash memory cells 310 are erased. If not the second even or odd page set of the half block, half sector, or half chip of the array of the dual charge retaining transistor NOR flash memory cells 310 is selected (Box 631) and is erased (Box 634) and erase verified (Box 636) until all pages of the page set are erased. When the page sets are examined (Box 652) and shown to have been erased the erase process is completed.

Refer now to FIG. 20 for a discussion of an erase operation with reprogramming of the selected block, sector, or whole chip of dual charge retaining transistor NOR flash memory cells 310. Referring to FIG. 20, the erase is structured to erase in half block, half sector, or half chip increments. The page set to be erased for the half block, half sector, or half chip is chosen (Box 660) and the pages of the unselected page set are inhibited. An erase counter N is initialized (Box 661) to contain an erase count and the first page to be erased is selected (Box 662). The selected non-inhibited pages are collectively erased (Box 664). Refer now to FIGS. 7-16 for voltage levels applied to the array of the dual charge retaining transistor NOR flash memory cells 310 to erase (Box 664) the selected word line pages of the dual charge retaining transistor NOR flash memory cells 310. The voltage levels are determined according whether the dual charge retaining transistor NOR flash memory cells 310 are floating gate or SONOS charge trapping flash nonvolatile transistors and are N-channel or P-channel flash nonvolatile transistors. Further, the erase threshold voltage level to which the dual charge retaining transistor NOR flash memory cells 310 are to be erase determine the erase biasing voltage levels. The unselected dual charge retaining transistor NOR flash memory cells 310 are similarly biased according the voltage levels of FIGS. 7-16 to inhibit any disturbances during the erasing operation.

The first page 315 of the selected word line pages of dual charge retaining transistor NOR flash memory cells 310 is then page verified (Box 666). Refer back to FIGS. 7-16 for the biasing voltage levels of the dual charge retaining transistor NOR flash memory cells 310 to be verified. The read bias voltage level V_{RDB} is applied as the power supply voltage source VDD to the selected global source lines GSL0, . . . , GSLn and the ground reference voltage level is applied to the global bit lines GBL0, . . . , GBLn. The sense amplifier detects the voltage level of the global bit lines GBL0, . . . , GBLn and thus the selected local bit lines. Dependent upon the erased threshold voltage level and the structure of the selected charge retaining transistors M0, the selected charge retaining transistor M0 are considered to have passed if the detected voltage is either the voltage level of the power supply voltage source VDD or the ground reference voltage level. FIGS. 7-16 show the pass and fail criteria for each of the structures and threshold.

If any of the selected pages of the charge retaining transistors M0 and M1 have not been sufficiently erased such that their threshold voltage level is beyond the limit of the erased threshold voltage level closest to the programmed threshold voltage level, the selected pages of the charge retaining transistors M0 and M1 have failed the verification (Box 666). The erase counter is incremented (Box 672) and the erase counter is compared (Box 674) to the maximum erase count Nmax. If the erase counter exceeds the maximum erase count Nmax, the nonvolatile memory device 300 has failed (Box 676). If the erase counter does not exceed the maximum erase count Nmax, the selected pages are again erased (Box 664) and erased verified (Box 666) iteratively until the page is verified (Box 666) as erased.

The page counter is examined (Box 668) to determine if the last page of the selected set of pages of the charge retaining transistors M0 and M1 have been verified. If the last page has not been verified (Box 668), the next page is selected (Box 670) and the page verified (Box 666). When all the pages are verified (Box 666), the page counter is reset (Box 678) to the first page. The first page of the selected pages is then verified (Box 680) that the threshold voltage levels of the charge retaining transistors M0 and M1 are beyond the limit of the erased threshold voltage level where the charge retaining transistors M0 and M1 are over-erased. If any of the charge retaining transistors M0 and M1 of the selected page have their erased threshold voltage level beyond this limit, the charge retaining transistors M0 and M1 are reprogrammed (Box 682) to bring the voltage threshold for the charge retaining transistors M0 and M1 of the page within the limits of the erased threshold voltage level. The page is then programmed verified (Box 680) and reprogrammed (Box 682) until all the charge retaining transistors M0 and M1 are verified as having their threshold voltage levels within the limits of the erased threshold voltage level. The page counter is examined (Box 684) to determine if the last page of the page set has been program verified (Box 680). If the last page has not been program verified (Box 680), the page counter is incremented (Box 686) and the next page of the selected pages of the half block, half sector, or half chip are then program verified (Box 680) and reprogrammed (Box 682) as necessary. This iterative process continues until all the pages are shown to have a threshold voltage level within the limits of the erased threshold voltage level when examined (Box 680). The array is examined (Box 688) to determine if both even and odd page sets of the half block, half sector, or half chip of the array of the dual charge retaining transistor NOR flash memory cells 310 are erased. If not the second even or odd page set of the half block, half sector, or half chip of the array of the dual charge retaining transistor NOR flash memory cells 310 is selected (Box 660) and is erased (Box 664), erase verified (Box 666), program verified (Box 680), and reprogrammed (Box 682), if necessary, until all pages of the page set are erased. When the page sets are examined (Box 682) and shown to have been erased the erase process is ended.

FIG. 21 is a flow chart of a read operation for selected dual charge retaining transistor NOR flash memory cells of an array of dual charge retaining transistor NOR flash memory cells. FIG. 7-16 are tables illustrating the voltage levels applied to the terminals for various embodiments of an array of dual charge retaining transistor NOR flash memory cells for a read operation. For this discussion, the selected dual charge retaining transistor NOR flash memory cells 310 are connected to the word lines WL0 and WL1 and the unselected dual charge retaining transistor NOR flash memory cells 310 are connected to the word lines WL2, WL3, . . . , WLm−1, and WLm. Referring to FIGS. 4-6 and 21, the read operation is started (Box 700) by the word line voltage control circuit 352 applying a read inhibit voltage level V_{I} to unselected word lines WL2, WL3, . . . , WLm−1, and WLm. The read reference voltage level V_{R} is applied to the selected word line WL0 or WL1 and the pass voltage level Vpass is applied to the unselected word line WL1 or WL0. The read reference voltage level VR and the pass voltage level Vpass are shown in FIGS. 7-16 for the various embodiments of the charge retaining transistors M0 and M1.

The sense amplifier 555 is activated to be connected to the global source lines GSL0, . . . , GSLn. The selected bit line select signals BLG0 and BLG1 are set to the gate select voltage level V_{RGS} to turn on the bit line select transistors 360a, . . . , 360n to pre-charge the local bit lines LBL0, LBL1, . . . , LBLn−1, and LBLn to a read bias voltage level V_{RDB}. The selected source line select signals SLG0 and SLG1 set to the gate select voltage level V_{RGS} to the source line select transistors 365a, . . . , 365n to apply either the power supply voltage level VDD or the ground reference voltage level to the local source lines LSL0, LSL1, . . . , LSLn−1, and LSLn dependent upon the structure of the charge retaining transistors M0 and M1. A cell current Icell passes through the charge retaining transistors M0 and M1 of the selected dual charge retaining transistor NOR flash memory cells 310 to the sense amplifier 555. The unselected bit line select signals BLG0 and BLG1 and the unselected source line select signals SLG0 and SLG1 are set to the read unselect voltage level V_{RUS} to deactivate the unselected local bit lines LBL0, LBL1, . . . , LBLn−1, and LBLn and the unselected local source lines LSL0, LSL1, . . . , LSLn−1, and LSLn.

The sense amplifier 555 employs the reference current Iref to determine the internal data state of the charge retaining transistors M0 connected to the selected word line WL0 or WL1. The cell current Icell is compared (Box 710) to the reference current Iref. The data state of the charge retaining transistors M0 or M1 connected to the selected word line WL0 or WL1 are then determined (Box 720). Upon the determination (Box 720) of the data state for the selected paired word line page of dual charge retaining transistor NOR flash memory cells 310, the read operation for the paired word line page of dual charge retaining transistor NOR flash memory cells 310 is ended.

FIG. 22 is a flow chart of a program operation for of a paired word line page of dual charge retaining transistor NOR flash memory cells of an array of dual charge retaining transistor NOR flash memory cells. FIGS. 7-16 are tables of the voltage levels applied to the terminals of various embodiments an array of dual charge retaining transistor NOR flash memory cells for a program operation and a program verify operation. For a discussion of the program operation of selected dual charge retaining transistor NOR flash memory cells 310, refer now to FIGS. 4-6 and 22. For this discussion, the selected dual charge retaining transistor NOR flash memory cells 310 are connected to the word lines WL0 and WL1 and the unselected dual charge retaining transistor NOR flash memory cells 310 are connected to the word lines WL2, WL3, . . . , WLm−1, and WLm. In FIG. 12 an input command is decoded to determine if it is a program operation. If the command is for an programming operation the operation is started (Box 730) with an erase procedure (Box 732) is performed to the charge retaining transistors M0 and M1 of the upper and lower word lines WL0 and WL1 of the selected paired word line page of dual charge retaining transistor NOR flash memory cells 310. The erase of the selected paired word line page 315 of dual charge retaining transistor NOR flash memory cells 310 is as described above in FIG. 18.

The counter N is initialized (Box 734) to be a program count. The charge retaining transistors M0 connected to the upper word line WL0 of the paired word line page of dual charge retaining transistor NOR flash memory cells 310 are programmed (Box 736). The program inhibit voltage level (V_{PGMI}) is applied to the unselected word lines WL2, WL3, . . . , WLm−1, and WLm. A program voltage V_{PGM} is applied to the upper word line WL0 of the selected single paired word line page 315 of dual charge retaining transistor NOR flash memory cells 310 to set the threshold voltage level of the selected charge retaining transistors M0 to the program threshold voltage level. The program threshold voltage level being as shown in FIGS. 7-16 for each of the embodiments of the charge retaining transistors M0 and M1. The program inhibit voltage level (V_{PGMI}) is applied to the lower word line WL1 of the selected single paired word line page of dual charge retaining transistor NOR flash memory cells 310.

The upper word line is then page program verified (Box 738). The unselected word lines WL2, WL3, . . . , WLm−1, and WLm are connected to receive the read inhibit voltage level V_{RI} and the unselected word line WL1 of the selected single paired word line page 315 of dual charge retaining transistor NOR flash memory cells 310 is connected to receive the read pass voltage level V_{PASS}. The selected word line WL0 of the selected single paired word line page 315 of dual charge retaining transistor NOR flash memory cells 310 is connected to receive the read voltage V_{R}.

The sense amplifier 555 is activated to be connected to the global bit lines GBL0, . . . , GBLn. The selected bit line select signals BLG0 and BLG1 are set to the voltage level of a read select voltage level V_{RGS} to turn on the bit line select transistors 360a, . . . , 360n to connect the global bit lines GBL0, . . . , GBLn to set the local bit lines LBL0, LBL1, . . . , LBLn−1, and LBLn to the read bias voltage level as shown in FIGS. 7-16. The selected source line select signals SLG0 and SLG1 are set to the voltage level of a read select voltage level V_{RGS} to turn on the source line select transistors 360a, . . . , 360n to connect the global source lines GSL0, . . . , GSLn to set the local source lines LSL0, LSL1, . . . , LSLn−1, and LSLn to the to apply either the power supply voltage level VDD or the ground reference voltage level dependent upon the structure of the charge retaining transistors M0 and M1 as shown in FIGS. 7-16. The sense amplifier 555 is activated to be connected to the global bit lines GBL0, . . . , GBLn to determine if the selected charge retaining transistors M0 are programmed according to the criteria detailed in FIGS. 7-16. If the selected charge retaining transistors M0 are not programmed according to the criteria of FIGS. 7-16, the program counter (N) is incremented (Box 739) and the program count is examined (Box 740) to determine if it equal to the maximum program count Nmax. If the program count exceeds the maximum program count Nmax, the nonvolatile memory device 300 has failed (Box 746). If the program count does not exceed the maximum program count Nmax, the upper page of the selected single paired word line page 315 of dual charge retaining transistor NOR flash memory cells 310 is programmed (Box 736) again and then program verified (Box 738) again. The programming (Box 736) and program verifying (Box 738) continues iteratively, until the upper page of the selected single paired word line page 315 of dual charge retaining transistor NOR flash memory cells 310 are programmed.

Upon completion of the programming (Box 736) and verification (Box 738) of the charge retaining transistors M0 of the upper word line WL0, the counter N is re-initialized (Box 741) to be a program count. The charge retaining transistors M1 connected to the lower word line WL1 of the paired word line page of dual charge retaining transistor NOR flash memory cells 310 are programmed (Box 742). The program inhibit voltage level (V_{PGMI}) is applied to the unselected word lines WL2, WL3, . . . , WLm−1, and WLm. A program voltage V_{PGM} is applied to the upper word line WL1 of the selected single paired word line page 315 of dual charge retaining transistor NOR flash memory cells 310 to set the threshold voltage level of the selected charge retaining transistors M0 to the program threshold voltage level. The program threshold voltage level being as shown in FIGS. 7-16 for each of the embodiments of the charge retaining transistors M0 and M1. The program inhibit voltage level (V_{PGMI}) is applied to the lower word line WL1 of the selected single paired word line page of dual charge retaining transistor NOR flash memory cells 310.

The upper word line is then page program verified (Box 738). The unselected word lines WL2, WL3, . . . , WLm−1, and WLm are connected to receive the read inhibit voltage level V_{RI} and the unselected upper word line WL0 of the selected single paired word line page 315 of dual charge retaining transistor NOR flash memory cells 310 is connected to receive the read pass voltage level V_{PASS}. The selected lower word line WL1 of the selected single paired word line page 315 of dual charge retaining transistor NOR flash memory cells 310 is connected to receive the read voltage V_{R}.

The sense amplifier 555 is activated to be connected to the global bit lines GBL0, . . . , GBLn. The selected bit line select signals BLG0 and BLG1 are set to the voltage level of a read select voltage level V_{RGS} to turn on the bit line select transistors 360a, . . . , 360n to connect the global bit lines GBL0, . . . , GBLn to set the local bit lines to LBL0, LBL1, . . . , LBLn−1, and LBLn to the read bias voltage level as shown in FIGS. 7-16. The selected source line select signals SLG0 and SLG1 are set to the voltage level of a read select voltage level V_{RGS} to turn on the source line select transistors 360a, . . . , 360n to connect the global source lines GSL0, . . . , GSLn to set the local source lines LSL0, LSL1, . . . , LSLn−1, and LSLn to the to apply either the power supply voltage level VDD or the ground reference voltage level dependent upon the structure of the charge retaining transistors M0 and M1 as shown in FIGS. 7-16. The sense amplifier 555 determines if the selected charge retaining transistors M1 are programmed according to the criteria detailed in FIGS. 7-16. If the selected charge retaining transistors M1 are not programmed according to the criteria of FIGS. 7-16, the program counter (N) is incremented (Box 744) and the program count is examined (Box 745) to determine if it equal to the maximum program count Nmax. If the program count exceeds the maximum program count Nmax, the nonvolatile memory device 300 has failed (Box 746). If the program count does not exceed the maximum program count Nmax, the upper page of the selected single paired word line page 315 of dual charge retaining transistor NOR flash memory cells 310 is programmed (Box 742) again and then program verified (Box 743) again. The programming (Box 742) and program verifying (Box 743) continues iteratively, until the lower page of the selected single paired word line page 315 of dual charge retaining transistor NOR flash memory cells 310 are programmed. Upon completion of the programming (Box 742) and verification (Box 743) of the charge retaining transistors M0 of the upper word line WL0, the programming process ends.

The embodiments of the dual charge retaining transistor NOR flash memory cells 310 are shown to be implementable in various devices structures employing either a floating gate or SONOS (or MONOS) charge trapping layer that is formed in a triple well or single well configuration. Further, the charge retaining transistors M0 and M1 of the dual charge retaining transistor NOR flash memory cells 310 may be implemented as either N-channel or P-channel transistors. The voltage level employed for the programming and erasing the dual charge retaining transistor NOR flash memory cells 310 provide robustness to avoid punch-through. The voltage and current operating levels are such that the device size is minimized to permit a high degree of cell scalability. The erase process makes the dual charge retaining transistor NOR flash memory cells 310 essentially over-erase free. The fabrication of the dual charge retaining transistor NOR flash memory cells 310 is based on today's standard flash nonvolatile memory technology. Dependent upon the device structures for the charge retaining transistors M0 and M1 of the dual charge retaining transistor NOR is flash memory cells 310, the programming and erasing process is selected to be Channel Fowler-Nordheim Tunneling, Edge Fowler-Nordheim Tunneling, and Band-to-Band Tunneling.

While this invention has been particularly shown and described with reference to the preferred embodiments thereof, it will be understood by those skilled in the art that various changes in form and details may be made without departing from the spirit and scope of the invention.

The invention claimed is:

1. A NOR flash memory cell comprising:
two serially connected charge retaining transistors, each of the charge retaining transistors comprising a charge retaining layer;
wherein a drain/source of a first of the dual charge retaining transistors is connected to a local bit line and a source/drain of a second of the dual charge retaining transistors connected to a local source line, and
wherein the drain/source of the commonly connected two serially connected charge retaining transistors are connected solely together.

2. The NOR flash memory cell of claim 1 wherein the drain/sources and source/drains of the two serially connected charge retaining transistors are formed in a diffusion well formed within a substrate.

3. The NOR flash memory cell of claim 2 wherein the diffusion well is formed within a deep diffusion well formed within the substrate.

4. The NOR flash memory cell of claim 1 wherein the two serially connected charge retaining transistors are N-channel charge retaining transistors.

5. The NOR flash memory cell of claim 1 wherein the two serially connected charge retaining transistors are P-channel charge retaining transistors.

6. The NOR flash memory cell of claim 4 wherein the N-channel charge retaining transistors are formed in a P-type well.

7. The NOR flash memory cell of claim 6 wherein the P-type well is formed in deep N-type well that is formed in a P-type substrate.

8. The NOR flash memory cell of claim 7 wherein the P-type well is formed in an N-type substrate.

9. The NOR flash memory cell of claim 5 wherein the P-channel charge retaining transistors are formed in an N-type well.

10. The NOR flash memory cell of claim 9 wherein the N-type well is formed in a deep P-type well that is formed in a N-type substrate.

11. The NOR flash memory cell of claim 1 wherein the charge retaining layer is formed of a charge storing floating gate

12. The NOR flash memory cell of claim 11 wherein the floating gate is a polycrystalline silicon layer or a metal layer.

13. The NOR flash memory cell of claim 1 wherein serially the charge retaining layer is formed of a charge trapping insulating layer.

14. The NOR flash memory cell of claim 1 wherein the charge trapping insulating layer is a silicon nitride.

15. The NOR flash memory cell of claim 1 wherein a selected charge retaining transistor of the two serially connected charge retaining transistors have programming and erasing biasing voltages are applied to a control gate, a drain or source, and a bulk region of the selected charge retaining transistor of the two serially connected charge retaining transistors to inject charge to or remove charge from the charge retaining layer to selectively program or erase the selected charge retaining transistor of the two serially connected charge retaining transistors.

16. The NOR flash memory cell of claim 15 wherein the selected charge retaining transistor of the serially connected charge retaining transistors is programmed by a combination of a band-to-band tunneling and a Fowler-Nordheim tunneling.

17. The NOR flash memory cell of claim 15 wherein the selected charge retaining transistor of the serially connected charge retaining transistors is erased by a Fowler Nordheim tunneling.
